(19) United States
(12) Patent Application Publication
(10) Pub. No.: US 2026/0157085 A1
(43) Pub. Date: Jun. 4, 2026

(54) DISPLAY DEVICE

(71) Applicant: Magnolia White Corporation, Tokyo (JP)

(72) Inventors: Yozo NAKAYASU, Tokyo (JP); Sho YANAGISAWA, Tokyo (JP); Ryota TAKASAKI, Tokyo (JP); Naoya IWAHASHI, Tokyo (JP)

(73) Assignee: Magnolia White Corporation, Tokyo (JP)

(21) Appl. No.: 19/403,295

(22) Filed: Nov. 28, 2025

(30) Foreign Application Priority Data
Nov. 29, 2024 (JP) 2024-208743

(51) Int. Cl. H10K 59/80; H10K 59/122

(52) U.S. Cl. CPC H10K 59/873; H10K 59/122

(57) ABSTRACT

According to one embodiment, a display device includes a lower electrode, a partition surrounding the lower electrode, a stacked film provided above the lower electrode, and a sealing layer formed of an inorganic insulating material, covering the stacked film, and provided above the partition. The sealing layer has a first side extending in a first direction, a second side extending in a second direction orthogonal to the first direction, and a third side extending in a direction different from the first and second directions and connecting the first side with the second side, in plan view. An angle formed by the first side and the third side is greater than 90 degrees and smaller than 180 degrees.

### CROSS-REFERENCE TO RELATED APPLICATIONS

This application is based upon and claims the benefit of priority from Japanese Patent Application No. 2024-208743, filed Nov. 29, 2024, the entire contents of which are incorporated herein by reference.

### FIELD

Embodiments described herein relate generally to a display device.

### BACKGROUND

Recently, a display device to which an organic light emitting diode (OLED) is applied as a display element has been put into practical use. In this type of display devices, a technique for improving the yield is required.

### BRIEF DESCRIPTION OF THE DRAWINGS

FIG. 1 is a diagram showing a configuration example of a display device according to a first embodiment.

FIG. 2 is a schematic plan view showing an example of layout of subpixels constituting a pixel.

FIG. 3 is a schematic cross-sectional view showing the display device along III-III line in FIG. 2.

FIG. 4 is a schematic cross-sectional view showing another example of the display device along III-III line in FIG. 2.

FIG. 5 is a schematic plan view showing an example of a configuration which can be applied to a partition and a sealing layer according to the first embodiment.

FIG. 6 is a schematic enlarged view showing a VI portion in FIG. 5.

FIG. 7 is a schematic plan view illustrating another example of the sealing layer.

FIG. 8 is a flowchart showing an example of a method of manufacturing the display device.

FIG. 9A is a schematic cross-sectional view showing a manufacturing process of the display device.

FIG. 9B is a schematic cross-sectional view showing a process following FIG. 9A.

FIG. 9C is a schematic cross-sectional view showing a process following FIG. 9B.

FIG. 9D is a schematic cross-sectional view showing a process following FIG. 9C.

FIG. 9E is a schematic cross-sectional view showing a process following FIG. 9D.

FIG. 9F is a schematic cross-sectional view showing a process following FIG. 9E.

FIG. 9G is a schematic cross-sectional view showing a process following FIG. 9F.

FIG. 9H is a schematic cross-sectional view showing a process following FIG. 9G.

FIG. 9I is a schematic cross-sectional view showing a process following FIG. 9H.

FIG. 9J is a schematic cross-sectional view showing a process following FIG. 9I.

FIG. 10A is a schematic plan view showing a manufacturing process of the display device.

FIG. 10B is a schematic plan view showing a process following FIG. 10A.

FIG. 10C is a schematic plan view showing a process following FIG. 10B.

FIG. 10D is a schematic plan view showing a process following FIG. 10C.

FIG. 10E is a schematic plan view showing a process following FIG. 10D.

FIG. 11 is a schematic enlarged view showing a XI portion in FIG. 10D.

FIG. 12A is a schematic plan view showing a process of manufacturing a display device according to a comparative example.

FIG. 12B is a schematic plan view showing a process following FIG. 12A.

FIG. 12C is a schematic plan view showing a process following FIG. 12B.

FIG. 13 is a schematic plan view showing a display device according to a second embodiment.

FIG. 14 is a schematic enlarged view showing a XIV portion in FIG. 13.

FIG. 15 is a schematic plan view showing a display device according to a third embodiment.

FIG. 16 is a schematic enlarged view showing a XVI portion in FIG. 15.

FIG. 17A is a schematic plan view showing a manufacturing process of a display device according to a third embodiment.

FIG. 17B is a schematic plan view showing a process following FIG. 17A.

FIG. 17C is a schematic plan view showing a process following FIG. 17B.

FIG. 18 is a schematic cross-sectional view showing the display device along XVIII-XVIII line in FIG. 17C.

FIG. 19 is a schematic cross-sectional view showing another example of the display device according to the fourth embodiment.

FIG. 20 is a schematic plan view showing a display device according to a fifth embodiment.

FIG. 21 is a schematic cross-sectional view showing the display device along XXI-XXI line in FIG. 20.

FIG. 22 is a schematic enlarged view showing a XXII portion in FIG. 20.

FIG. 23 is a schematic plan view showing a display device according to a comparative example.

FIG. 24 is a schematic plan view showing a modified example of the display device.

### DETAILED DESCRIPTION

In general, according to one embodiment, a display device includes a lower electrode, a partition surrounding the lower electrode, a stacked film provided above the lower electrode, and a sealing layer formed of an inorganic insulating material, covering the stacked film, and provided above the partition. The sealing layer has a first side extending in a first direction, a second side extending in a second direction orthogonal to the first direction, and a third side extending in a direction different from the first and second directions and connecting the first side with the second side, in plan view. An angle formed by the first side and the third side is greater than 90 degrees and smaller than 180 degrees.

According to another embodiment, a display device includes a first lower electrode, a second lower electrode, a third lower electrode, a partition surrounding the first lower electrode, the second lower electrode, and the third lower electrode, a first stacked film provided above the first lower electrode, a second stacked film provided above the second lower electrode, a first sealing layer formed of an inorganic insulating material, covering the first stacked film, and provided above the partition, and a second sealing layer formed of an inorganic insulating material, covering the second stacked film, and provided above the partition. The first sealing layer has a fourth side extending in a first direction in plan view. The second sealing layer has a fifth side extending in a second direction orthogonal to the first direction, and a sixth side extending in a direction different from the first and second directions and connected with the fifth side, in plan view. The first sealing layer and the second sealing layer form an area overlapping with the third lower electrode. An interior angle of the area, i.e., an angle formed by the fourth side and the sixth side is greater than 90 degrees and smaller than 180 degrees.

According to yet another embodiment, a display device includes a first lower electrode, a second lower electrode, a third lower electrode, a partition surrounding the first lower electrode, the second lower electrode, and the third lower electrode, a first stacked film provided above the first lower electrode, a second stacked film provided above the second lower electrode, a first sealing layer formed of an inorganic insulating material, covering the first stacked film, and provided above the partition, and a second sealing layer formed of an inorganic insulating material, covering the second stacked film, and provided above the partition. The first sealing layer has a fourth side extending in a first direction, and a seventh side extending in a direction different from the second direction orthogonal to the first direction, and connected with the fourth side, in plan view. The first sealing layer and the second sealing layer form an area overlapping with the third lower electrode. An interior angle of the area, i.e., an angle formed by the fourth side and the seventh side is greater than 90 degrees and smaller than 180 degrees.

According to these configurations, a display device capable of improving a yield can be provided.

Embodiments will be described hereinafter with reference to the accompanying drawings. The disclosure is merely an example, and proper changes within the spirit of the invention, which are easily conceivable by a person of ordinary skill in the art, are included in the scope of the invention as a matter of course. In addition, in some cases, in order to make the description clearer, the widths, thicknesses, shapes and the like, of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary. In the figures, an X-axis, a Y-axis and a Z-axis orthogonal to each other are described to facilitate understanding as needed. A direction parallel to the X-axis is referred to as a first direction X. A direction parallel to the Y-axis is referred to as a second direction Y. A direction parallel to the Z-axis is referred to as a third direction Z. Viewing various elements parallel to the third direction Z is referred to as plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

### First Embodiment

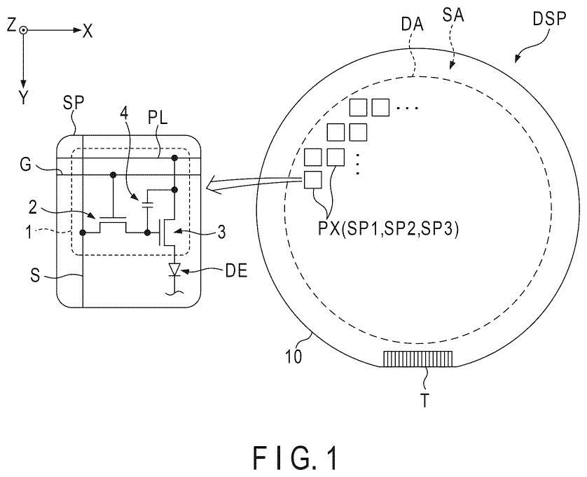

FIG. 1 is a diagram showing a configuration example of a display device DSP according to an embodiment. The display device DSP comprises an insulating substrate 10. The substrate 10 has a display area DA where images are displayed, and a surrounding area SA around the display area DA. The substrate 10 may be glass or a resinous film having flexibility.

In the embodiment, the shape of the substrate 10 and the display area DA in plan view is a circular shape. However, the shape of the substrate 10 and the display area DA in plan view is not limited to a circle, but may be the other shape such as a rectangle, a square or an oval.

The display area DA includes a plurality of pixels PX arrayed in matrix in the first direction X and the second direction Y. Each pixel PX includes a plurality of subpixels SP which display different colors. It is assumed in this embodiment that each pixel PX includes a blue subpixel SP1, a green subpixel SP2, and a red subpixel SP3. Each pixel PX may include a subpixel SP which displays the other color such as white in addition to the subpixels SP1, SP2, and SP3 or instead of one of the subpixels SP1, SP2, and SP3.

The display device DSP further comprises a terminal portion T provided in the surrounding area SA. For example, a flexible printed circuit which applies voltage and signals for driving the display device DSP is connected to the terminal portion T.

Each subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements composed of thin-film transistors.

In the display area DA, a plurality of scanning lines G which supply a scanning signal to the pixel circuit 1 of each subpixel SP, a plurality of signal lines S which supply a video signal to the pixel circuit 1 of each subpixel SP, and a plurality of power lines PL are provided. In the example of FIG. 1, the scanning lines G and the power lines PL extend in the first direction X, and the signal lines S extend in the second direction Y.

A gate electrode of the pixel switch 2 is connected to the scanning line G. One of a source electrode and a drain electrode of the pixel switch 2 is connected to the signal line S. The other electrode is connected to the gate electrode of the drive transistor 3 and the capacitor 4. In the drive transistor 3, one of a source electrode and a drain electrode is connected to a power line PL and the capacitor 4, and the other electrode is connected to the display element DE.

Incidentally, the configuration of the pixel circuit 1 is not limited to the example shown in the figure. For example, the pixel circuit 1 may comprise more thin-film transistors and more capacitors.

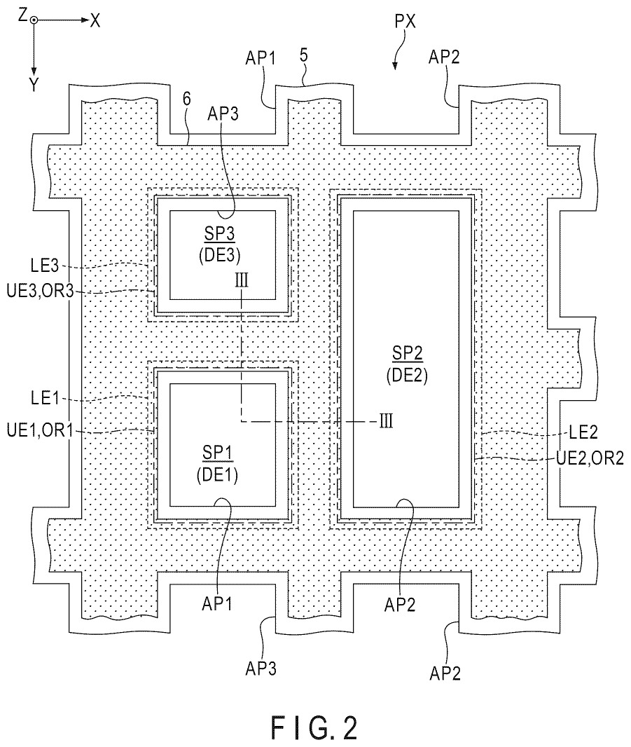

FIG. 2 is a schematic plan view showing an example of the layout of subpixels SP1, SP2, and SP3 constituting a pixel PX. In the example of FIG. 2, the subpixels SP1 and SP3 are arranged in the second direction Y. In addition, each of the subpixels SP1 and SP3 is adjacent to the subpixel SP2 in the first direction X.

When the subpixels SP1, SP2, and SP3 are provided in this layout, a column in which the subpixels SP1 and SP3 are alternately provided in the second direction Y and a column in which a plurality of subpixels SP2 are repeatedly provided in the second direction Y are formed in the display area DA. These columns are alternately arranged in the first direction X. Incidentally, the layout of the subpixels SP1, SP2, and SP3 is not limited to the example of FIG. 2.

A rib layer 5 (inorganic insulating layer) is provided in the display area DA. The rib layer 5 has pixel apertures AP1, AP2, and AP3 in the respective subpixels SP1, SP2, and SP3.

In the example of FIG. 2, each of the pixel apertures AP1, AP2, and AP3 has a rectangular shape. The area of the pixel aperture AP1 is larger than that of the pixel aperture AP3. In addition, the area of the pixel aperture AP2 is larger than that of the pixel aperture AP1. The pixel aperture AP2 has a rectangular shape which is more elongated in the Y-direction than the pixel apertures AP1 and AP3. However, the shape of the pixel apertures AP1, AP2, and AP3 is not limited to this example.

The subpixel SP1 comprises a lower electrode LE1 (first lower electrode), an upper electrode UE1, and an organic layer OR1 overlapping with the pixel aperture AP1. The subpixel SP2 comprises a lower electrode LE2 (second lower electrode), an upper electrode UE2, and an organic layer OR2 overlapping with the pixel aperture AP2. The subpixel SP3 comprises a lower electrode LE3 (third lower electrode), an upper electrode UE3, and an organic layer OR3 overlapping with the pixel aperture AP3.

Portions of the lower electrode LE1, the upper electrode UE1, and the organic layer OR1, which overlap with the pixel aperture AP1 constitute a display element DE1 of the subpixel SP1. Portions of the lower electrode LE2, the upper electrode UE2, and the organic layer OR2, which overlap with the pixel aperture AP2 constitute a display element DE2 of the subpixel SP2. Portions of the lower electrode LE3, the upper electrode UE3, and the organic layer OR3, which overlap with the pixel aperture AP3 constitute a display element DE3 of the subpixel SP3. Each of the display elements DE1, DE2, and DE3 may further include a cap layer to be described later. The rib layer 5 surrounds each of these display elements DE1, DE2, and DE3.

A conductive partition 6 is provided above the rib layer 5. The partition 6 functions as lines which apply a common voltage to the upper electrodes UE1, UE2, and UE3. The partition 6 overlaps with the rib layer 5 as a whole and has a planar shape similar to that of the rib layer 5. The partition 6 is formed to surround the lower electrodes LE1, LE2, and LE3.

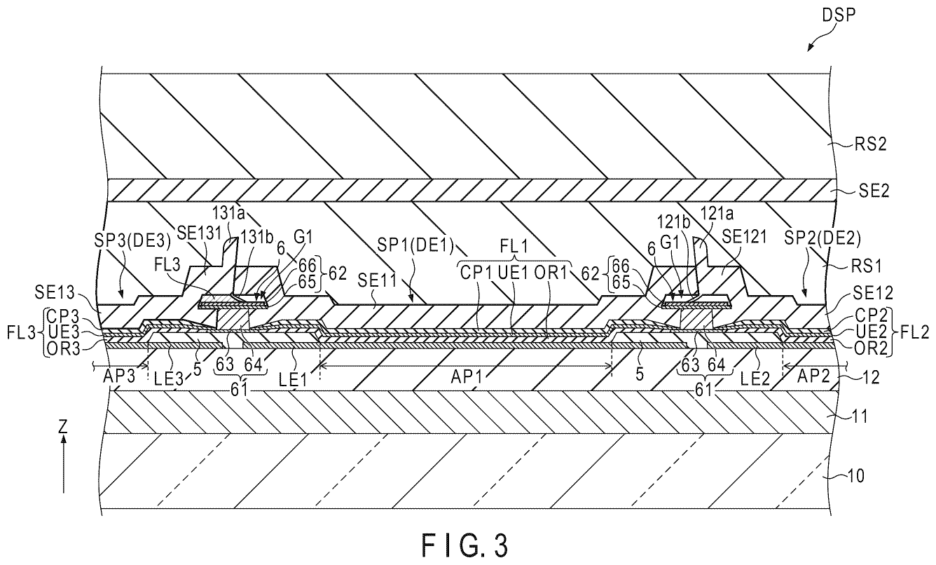

FIG. 3 is a schematic cross-sectional view showing the display device DSP along III-III line in FIG. 2. A circuit layer 11 is provided on the above-described substrate 10. The circuit layer 11 includes various circuits and lines such as the pixel circuit 1, the scanning line G, the signal line S, and the power line PL shown in FIG. 1. The circuit layer 11 is covered with an organic insulating layer 12. The organic insulating layer 12 functions as a planarization film which planarizes the irregularities formed by the circuit layer 11.

The lower electrodes LE1, LE2, and LE3 are provided on the organic insulating layer 12. The rib layer 5 is provided on the organic insulating layer 12 and the lower electrodes LE1, LE2, and LE3. End portions of the lower electrodes LE1, LE2, and LE3 are covered with the rib layer 5. Although not shown in the cross-section of FIG. 3, the lower electrodes LE1, LE2, and LE3 are connected to the respective pixel circuits 1 of the circuit layer 11 through contact holes provided in the organic insulating layer 12.

The partition 6 includes a conductive lower portion 61 provided on the rib layer 5 and an upper portion 62 provided on the lower portion 61. The upper portion 62 has a width greater than that of the lower portion 61. As a result, the both end portions of the upper portion 62 protrude relative to the side surfaces of the lower portion 61. This shape of the partition 6 is referred to as an overhang shape.

In the example of FIG. 3, the lower portion 61 includes a bottom layer 63 provided on the rib layer 5, and a stem layer 64 provided on the bottom layer 63. For example, the bottom layer 63 is formed so as to be thinner than the stem layer 64. In the example of FIG. 3, the both end portions of the bottom layer 63 protrude from the side surfaces of the stem layer 64.

In addition, in the example of FIG. 3, the upper portion 62 includes a first top layer 65, and a second top layer 66 provided on the first top layer 65. For example, the width of the second top layer 66 is slightly smaller than that of the first top layer 65. The configuration is not limited to this example. The first top layer 65 and the second top layer 66 may have the same width.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 are in contact with the lower portions 61 of the partition 6.

The display element DE1 includes a cap layer CP1 which covers the upper electrode UE1. The display element DE2 includes a cap layer CP2 which covers the upper electrode UE2. The display element DE3 includes a cap layer CP3 which covers the upper electrode UE3. The cap layers CP1, CP2, and CP3 function as optical adjustment layers which improve the extraction efficiency of the light emitted from the organic layers OR1, OR2, and OR3, respectively.

In the following descriptions, a multilayer body including the organic layer OR1, the upper electrode UE1, and the cap layer CP1 is referred to as a stacked film FL1 (first stacked film), a multilayer body including the organic layer OR2, the upper electrode UE2, and the cap layer CP2 is referred to as a stacked film FL2 (second stacked film), and a multilayer body including the organic layer OR3, the upper electrode UE3, and the cap layer CP3 is referred to as a stacked film FL3 (third stacked film). The stacked films FL1, FL2, and FL3 are provided above the lower electrodes LE1, LE2, and LE3. In addition, the rib layer 5 is provided under the partition 6 and the stacked films FL1, FL2, and FL3.

Sealing layers SE11, SE12, and SE13 are provided in the subpixels SP1, SP2, and SP3, respectively. In the present embodiment, the sealing layer SE11 corresponds to a first sealing layer, the sealing layer SE12 corresponds to a second sealing layer, and the sealing layer SE13 corresponds to a third sealing layer.

The sealing layer SE11 continuously covers the display element DE1 (stacked film FL1) and the partition 6 around the display element DE1. The sealing layer SE12 continuously covers the display element DE2 (stacked film FL2) and the partition 6 around the display element DE2. The sealing layer SE13 continuously covers the display element DE3 (stacked film FL3) and the partition 6 around the display element DE3.

The sealing layers SE11, SE12, and SE13 are covered with a resin layer RS1. The resin layer RS1 is covered with a sealing layer SE2. The sealing layer SE2 is covered with a resin layer RS2. The resin layers RS1 and RS2 and the sealing layer SE2 are continuously provided in at least the entire display area DA and partly extend to the surrounding area SA.

A cover member such as a polarizer, a touch panel, a protective film or a cover glass may be further provided above the resin layer RS2. This cover member may be attached to the resin layer RS2 via, for example, an adhesive layer such as an optical clear adhesive (OCA). The electrodes which constitute the above-described touch panel may be provided on the sealing layer SE2.

In the example of FIG. 3, the end portions of the sealing layers SE11 and SE12 located on the partition 6 between the subpixels SP1 and SP2 are in contact with (closely attached to) each other. In addition, the end portions of the sealing layers SE11 and SE13 located on the partition 6 between the subpixels SP1 and SP3 are in contact with (closely attached to) each other. Furthermore, although not shown in the figure, the end portions of the sealing layers SE12 and SE13 located on the partition 6 between the subpixels SP2 and SP3 are in contact with (closely attached to) each other.

Focus on the sealing layer SE12 will be made here. The sealing layer SE12 has an overlapping portion SE121 located above the partition 6. The overlapping portion SE121 is in contact with the end portion of the sealing layer SE11. The overlapping portion SE121 may include a protruding portion 121a that protrudes upwardly. The protruding portion 121a is located above the partition 6 between the subpixels SP1 and SP2 so as to be higher than the sealing layer SE11.

In addition, the overlapping portion SE121 may further include an extending portion 121b that extends toward a gap G1 formed between the sealing layer SE11 and the upper portion 62 of the partition 6. This gap occurs due to disappearance of the stacked film FL1 during the manufacturing process.

The stacked film FL2 may be provided between the partition 6 and the overlapping portion SE121. Incidentally, this stacked film FL2 may disappear during the manufacturing process. In this case, a gap occurs between the sealing layer SE12 and the partition 6.

Similarly, focus on the sealing layer SE13 will be made here. The sealing layer SE13 has an overlapping portion SE131 located above the partition 6. The overlapping portion SE131 is in contact with the end portion of the sealing layer SE11. The overlapping portion SE131 may include a protruding portion 131a that protrudes upwardly. The protruding portion 131a is located above the partition 6 between the subpixels SP1 and SP3 so as to be higher than the sealing layer SE11.

In addition, the overlapping portion SE131 may further include an extending portion 131b that extends toward a gap G1 formed between the sealing layer SE11 and the upper portion 62 of the partition 6. This gap occurs due to disappearance of the stacked film FL1 during the manufacturing process.

The stacked film FL3 may be provided between the partition 6 and the overlapping portion SE131. Incidentally, if this stacked film FL3 disappears during the manufacturing process, a gap occurs between the sealing layer SE13 and the partition 6.

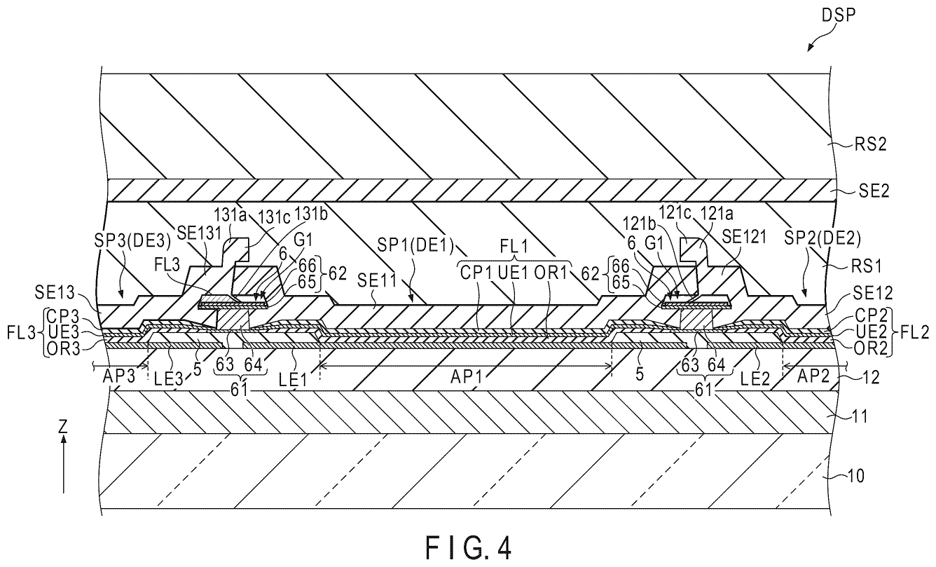

FIG. 4 is a schematic cross-sectional view showing another example of the display device DSP along III-III line in FIG. 2. In FIG. 4, the shapes of the overlapping portions SE121 and SE131 of the sealing layers SE12 and SE13 are different from those in the example shown in FIG. 3.

Focus on the sealing layer SE12 will be made here. The protruding portion 121a of the sealing layer SE12 may overlap with the sealing layer SE11. In the example of FIG. 4, the protruding portion 121a includes a portion 121c that overlaps with the sealing layer SE11. The partition 6, the sealing layer SE11, and the protruding portion 121a of the sealing layer SE12 are arranged in this order in the third direction Z. The portion 121c may or may not be in contact with the sealing layer SE11.

Similarly, focus on the sealing layer SE13 will be made here. The protruding portion 131a of the sealing layer SE13 may overlap with the sealing layer SE11. In the example of FIG. 4, the protruding portion 131a includes a portion 131c that overlaps with the sealing layer SE11. The partition 6, the sealing layer SE11, and the protruding portion 131a of the sealing layer SE13 are arranged in this order in the third direction Z. The portion 131c may or may not be in contact with the sealing layer SE11.

Although not shown in FIG. 3 or FIG. 4, focus on the area above the partition 6 between the subpixels SP2 and SP3 will be made here. The overlapping portion SE131 may include a protruding portion 131a that protrudes upwardly. The protruding portion 131a is located above the sealing layer SE12. In addition, in the example of FIG. 4, the partition 6, the sealing layer SE12, and the protrusion 131a of the sealing layer SE13 are provided above the partition 6 between the subpixels SP2 and SP3 and arranged in this order in the third direction Z.

The organic insulating layer 12 is formed of an organic insulating material such as polyimide. Each of the rib layer 5 and the sealing layers SE11, SE12, SE13, and SE2 is formed of an inorganic insulating material such as silicon nitride (SiNx), silicon oxide (SiOx), or silicon oxynitride (SiON). In one example, the rib layer 5 is formed of silicon oxynitride, and each of the sealing layers SE11, SE12, SE13, and SE2 is formed of silicon nitride. Each of the resin layers RS1 and RS2 is formed of, for example, a resinous material (organic insulating material) such as epoxy resin or acrylic resin.

Each of the lower electrodes LE1, LE2, and LE3 includes a reflective layer formed of, for example, silver, and a pair of conductive oxide layers covering upper and lower surfaces of the reflective layer. Each of the conductive oxide layers can be formed of, for example, a transparent conductive oxide such as indium tin oxide (ITO), indium zinc oxide (IZO) or indium gallium zinc oxide (IGZO).

The upper electrodes UE1, UE2, and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

Each of the organic layers OR1, OR2, and OR3 is composed of a plurality of thin films including a light emitting layer. In one example, each of the organic layers OR1, OR2, and OR3 has a structure in which a hole injection layer, a hole transport layer, an electron blocking layer, a light emitting layer, a hole blocking layer, an electron transport layer, and an electron injection layer are stacked in order in the third direction Z. However, each of the organic layers OR1, OR2, and OR3 may have the other structure such as a so-called tandem structure including a plurality of light emitting layers.

Each of the cap layers CP1, CP2, and CP3 has, for example, a multilayer structure in which a plurality of transparent layers are stacked. These transparent layers may include a layer formed of an inorganic material and a layer formed of an organic material. In addition, the transparent layers have refractive indices different from each other. For example, the refractive indices of these transparent layers are different from the refractive indices of the upper electrodes UE1, UE2, and UE3 and the refractive indices of the sealing layers SE11, SE12, and SE13. Incidentally, at least one of the cap layers CP1, CP2, and CP3 may be omitted.

The bottom layer 63 and the stem layer 64 of the partition 6 are formed of a metal material. For the metal material of the bottom layer 63, for example, molybdenum, titanium, titanium nitride (TiN), a molybdenum-tungsten alloy (MoW), or a molybdenum-niobium alloy (MoNb) can be used. For the metal material of the stem layer 64, for example, aluminum, an aluminum-neodymium alloy (AlNd), an aluminum-yttrium alloy (AlY), or an aluminum-silicon alloy (AlSi) can be used. Incidentally, the stem layer 64 may be formed of an insulating material.

The first top layer 65 of the partition 6 is formed of, for example, a metal material. In addition, the second top layer 66 of the partition 6 is formed of, for example, a conductive oxide. For the metal material forming the first top layer 65, for example, titanium, titanium nitride, molybdenum, tungsten, a molybdenum-tungsten alloy, or a molybdenum-niobium alloy can be used. For the conductive oxide forming the second top layer 66, for example, ITO or IZO can be used. Incidentally, the upper portion 62 may include three or more layers or may be composed of a single layer. Furthermore, the upper portion 62 may include a layer formed of an insulating material.

A common voltage is applied to the partition 6. This common voltage is applied to each of the upper electrodes UE1, UE2, and UE3 which are in contact with the lower portions 61. A pixel voltage is applied to the lower electrodes LE1, LE2, and LE3 through the pixel circuits 1 provided in the subpixels SP1, SP2, and SP3, respectively, based on the video signals of the signal lines S.

The organic layers OR1, OR2, and OR3 emit light based on the application of voltages. More specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2, and OR3 may emit light exhibiting the same color (for example, white). In this case, the display device DSP may comprise color filters which convert the light emitted from the light emitting layers into light exhibiting colors corresponding to the subpixels SP1, SP2, and SP3. In addition, the display device DSP may comprise a layer including a quantum dot which generates light exhibiting colors corresponding to the subpixels SP1, SP2, and SP3 by the excitation caused by the light emitted from the light emitting layers.

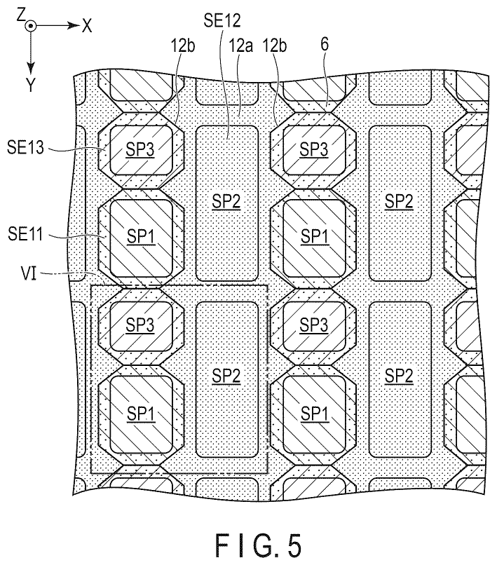

FIG. 5 is a schematic plan view showing an example of a configuration which can be applied to the partition 6 and the sealing layers SE11, SE12, and SE13 according to the present embodiment. In FIG. 5, the sealing layer SE11 has a downward-sloping line pattern, the sealing layer SE12 has a dot pattern, and the sealing layer SE13 has an upward-sloping line pattern. In addition, the partition 6 has a dot pattern that is coarser than that of the sealing layer SE12.

As shown in FIG. 5, the sealing layer SE11 covers the subpixel SP1, the sealing layer SE12 covers the subpixel SP2, and the sealing layer SE13 covers the subpixel SP3. The sealing layers SE11 and SE13 are formed for the sub-pixels SP1 and SP3, respectively. For example, the sealing layers SE12 are continuously formed over a plurality of subpixels SP2 arranged in the second direction Y. Incidentally, the sealing layer SE12 may be formed for each subpixel SP2. As described with reference to FIG. 3, the sealing layers SE11, SE12, and SE13 are not spaced apart from each other.

The sealing layers SE11 and SE13 have, for example, a polygonal shape in plan view. In the example of FIG. 5, the planar shape of the sealing layers SE11 and SE13 is an octagonal shape. The sealing layer SE12 includes a main body 12a overlapping with the subpixels SP2, and a plurality of outwardly extending portions 12b. The outwardly extending portions 12b extend from the main body 12a toward an outside of the subpixel SP2. More specifically, the plurality of outwardly extending portions 12b extend in the second direction Y and a direction opposite to the second direction Y.

The outwardly extending portion 12b is located at a corner portion formed by the sealing layers SE11 and SE13. Incidentally, the planar shapes of the sealing layers SE11, SE12, and SE13 are not limited to this example.

FIG. 6 is a schematic enlarged view showing a VI portion in FIG. 5. In FIG. 6, focus on the sealing layer SE13 is mainly made and the other elements such as the sealing layers SE11 and SE12 are omitted.

The sealing layer SE13 has two sides L1, two sides L2, two sides L31, and two sides L32 in plan view. In the present embodiment, the side L1 corresponds to a first side, the side L2 corresponds to a second edge, and the side L31 corresponds to a third side.

The side L1 corresponds to a side facing the end portion of the sealing layer SE11. More specifically, the side L1 corresponds to the side which is in contact with the end portion of the sealing layer SE11. The sides L2, L31, and L32 correspond to the sides facing the end portions of the sealing layers SE12. More specifically, the sides L2, L31, and L32 correspond to the sides which are in contact with the end portions of the sealing layers SE12.

The side L1 extends in the first direction, and the side L2 extends in the second direction. The sides L31 and L32 extend in directions different from the first direction X and the second direction Y. The side L31 extends in, for example, direction D1 which intersects the first direction X at an acute angle counterclockwise. The side L32 extends in, for example, direction D2 which intersects the first direction X at an acute angle counterclockwise.

The sides L31 and L32 connect the sides L1 and L2. In this case, connecting implies not only a case where the elements are directly connected, but also a case where the elements are connected via the other element. In the example of FIG. 6, the sides L31 and L32 are directly connected to the sides L1 and L2, respectively.

In addition, focus on the relationship with the partition 6 will be made here. Each of the sides L1, L2, L31, and L32 overlaps with the partition 6. In other words, the sides L1, L2, L31, and L32 are provided above the upper portion 62 of the partition 6. In addition, from another viewpoint, the sides L1, L2, L31, and L32 do not overlap with the apertures in the partition 6.

Focus on the corner portion CN3 formed by the sides L1 and edge L31 is made here, and an angle formed by the side L1 and the side L31 is defined as angle θ1. Focus on the sealing layer SE13 will be made here. The angle θ1 corresponds to an interior angle of the sealing layer SE13. The angle θ1 is, for example, an obtuse angle. In other words, the angle θ1 is greater than 90 degrees and smaller than 180 degrees (90 degrees<θ1<180 degrees). In one example, the angle θ1 is 120 degrees or more and 150 degrees or less (120 degrees<θ1<150 degrees). More specifically, the angle θ1 is 135 degrees.

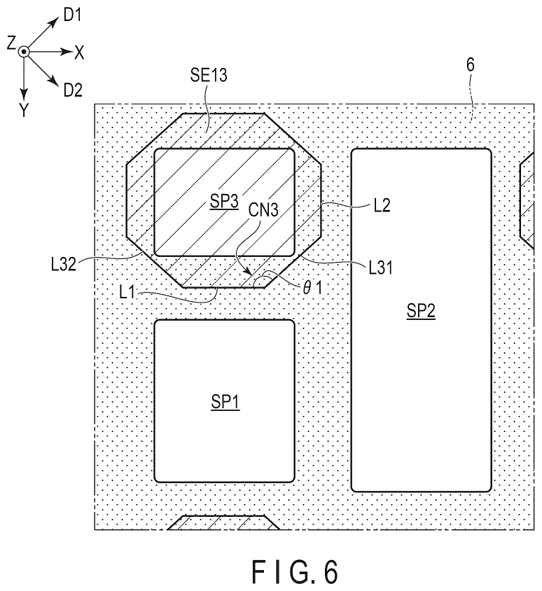

FIG. 7 is a schematic plan view illustrating another example of the sealing layer SE13. The corner portion CN3 of the sealing layer SE13 is enlarged in FIG. 7.

The sealing layer SE13 may further include a curved portion RL1. The curved portion RL1 has an arc shape (rounded shape). The curved portion RL1 connects the sides L1 and L31. In other words, the side L31 of the sealing layer SE13 is connected to the side L1 via the curved portion RL1.

In this case, the angle θ1 corresponds to an angle formed between extension L1E of the side L1 and extension L3E of the side L31. In other words, the angle θ1 includes not only the angle of the corner CN3 in a case where the sides L1 and L31 are directly connected to each other, but also the angle of the corner CN3 in a case where the extension L1E of the side L1 and the extension L3E of the side L31 are connected to each other.

Incidentally, the corner CN3 of the sealing layer SE13 has been described with reference to FIG. 6 and FIG. 7, but the other corners of the sealing layer SE13 are configured in the same manner.

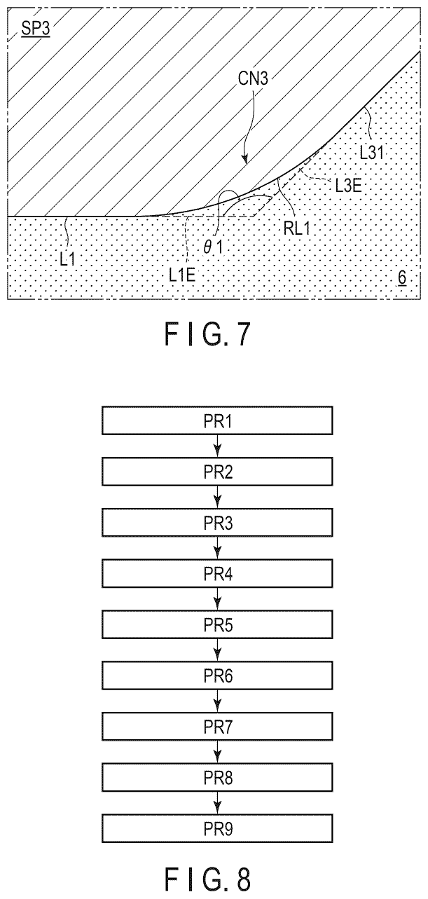

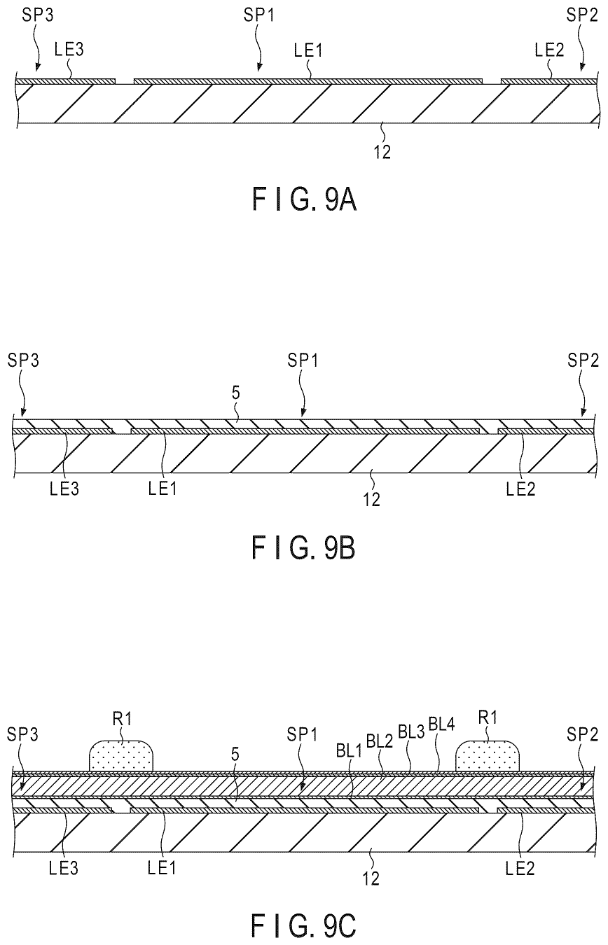

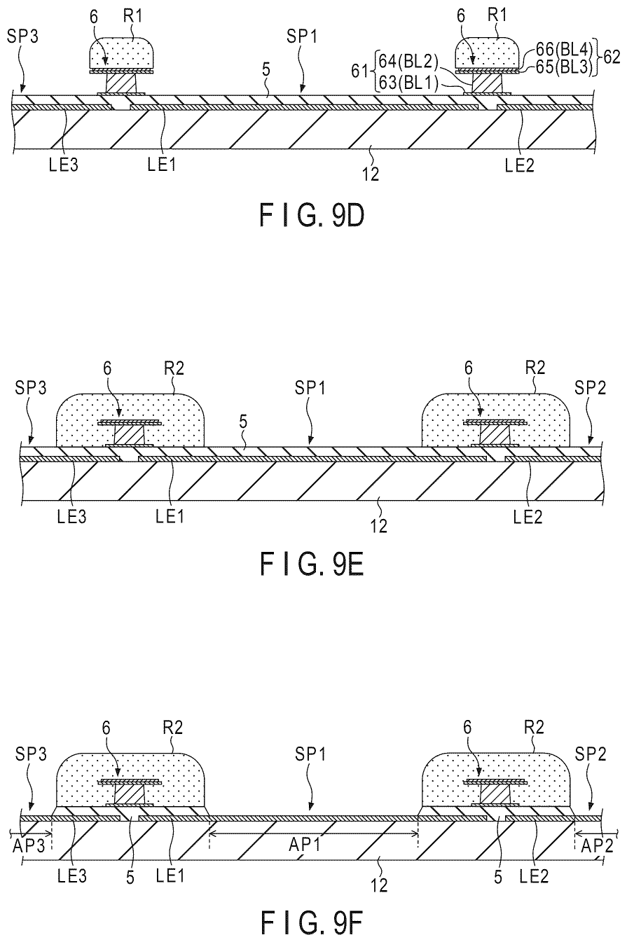

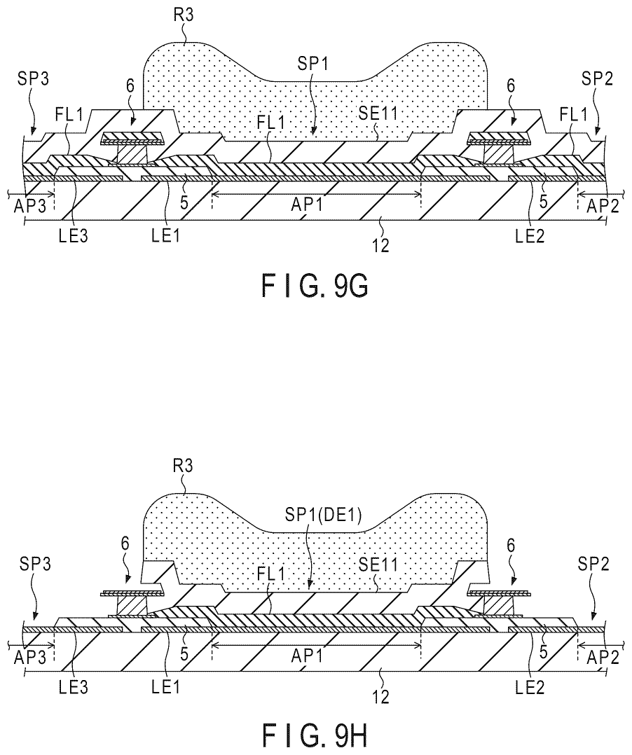

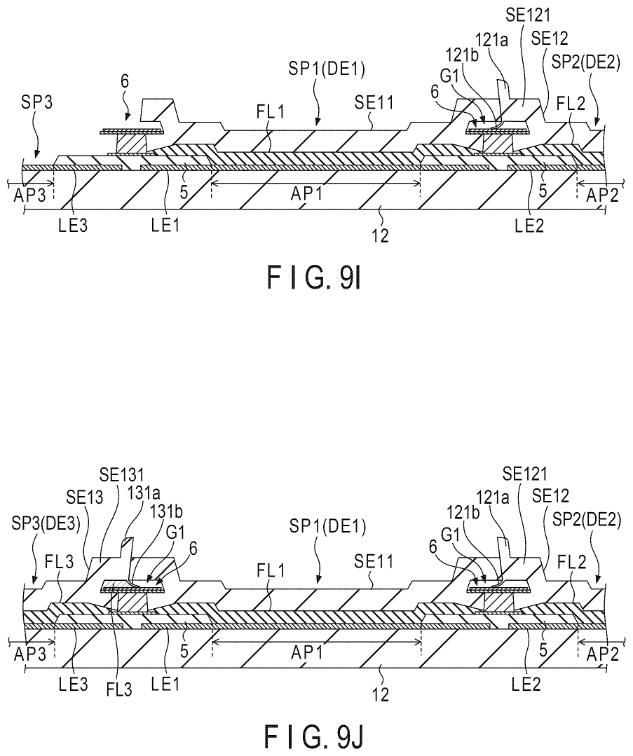

Next, an example of a method of manufacturing the display device DSP will be described. FIG. 8 is a flowchart showing an example of a method of manufacturing the display device DSP. FIG. 9A to FIG. 9J are schematic cross-sectional views showing processes of manufacturing the display device DSP. In FIG. 9A to FIG. 9J, focus on the display area DA is mainly made and the elements located under the organic insulating layer 12 are omitted.

To form the display device DSP, first, the circuit layer 11 and the organic insulating layer 12 are formed on the substrate 10 (process PR1 in FIG. 8). Subsequently, as shown in FIG. 9A, the lower electrodes LE1, LE2, and LE3 are formed on the organic insulating layer 12 (process PR2 in FIG. 8).

Subsequently, as shown in FIG. 9B, the rib layer 5 which covers the lower electrodes LE1, LE2, and LE3 is formed (process PR3 in FIG. 8). At this time, the pixel aperture AP1, AP2 or AP3 is not provided in the rib layer 5. The rib layer 5 can be formed by chemical vapor deposition (CVD).

After the formation of the rib layer 5, a process for forming the partition 6 is performed (process PR4 in FIG. 8). In the process PR4, as shown in FIG. 9C, a first layer BL1 which is processed so as to be the bottom layer 63, a second layer BL2 which is processed so as to be the stem layer 64, a third layer BL3 which is processed so as to be the first top layer 65, and a fourth layer BL4 which is processed so as to be the second top layer 66 are formed in order. Furthermore, a resist R1 is provided on the fourth layer BL4. The resist R1 has been patterned into the shape of the partition 6. The first layer BL1, the second layer BL2, the third layer BL3, and the fourth layer BL4 can be formed by, for example, sputtering.

After that, the first layer BL1, the second layer BL2, the third layer BL3, and the fourth layer BL4 are patterned using the resist R1 as a mask. In one example, the first layer BL1 is formed of titanium nitride, the second layer BL2 is formed of aluminum, the third layer BL3 is formed of titanium, and the fourth layer BL4 is formed of ITO. In this case, the above patterning may include wet etching for removing the portion of the fourth layer BL4 exposed from the resist R1, dry etching for removing the portions of the first, second and third layers BL1, BL2, and BL3 exposed from the resist R1, and wet etching for reducing the width of the second layer BL2.

As shown in FIG. 9D, the partition 6 is formed in the display area DA through the process PR4. After the formation of the partition 6, the resist R1 is removed (peeled off). In the above-described wet etching for reducing the width of the second layer BL2, the second top layer 66 (fourth layer BL4) may also be slightly corroded. When this corrosion occurs, the width of the second top layer 66 becomes smaller than that of the first top layer 65.

Subsequently, a process for providing the pixel apertures AP1, AP2, and AP3 is performed (process PR5 in FIG. 8). In this process PR5, as shown in FIG. 9E, a resist R2 which covers the partition 6 is formed. Furthermore, dry etching for the rib layer 5 is performed using the resist R2 as a mask. As a result, as shown in FIG. 9F, the pixel apertures AP1, AP2, and AP3 from which the lower electrodes LE1, LE2, and LE3 are exposed are formed in the rib layer 5. After the above-described dry etching, the resist R2 is removed (peeled off).

After the process PR5, a process for forming the display element DE1 is performed (process PR6 in FIG. 8). To form the display element DE1, first, as shown in FIG. 9G, the stacked film FL1 and the sealing layer SE11 are formed. As shown in FIG. 3, the stacked film FL1 includes the organic layer OR1 which is in contact with the lower electrode LE1 through the pixel aperture AP1, the upper electrode UE1 which covers the organic layer OR1, and the cap layer CP1 which covers the upper electrode UE1. The organic layer OR1, the upper electrode UE1, and the cap layer CP1 can be formed by, for example, vapor deposition. In addition, the sealing layer SE11 can be formed by, for example, CVD.

The stacked film FL1 and the sealing layer SE11 are formed in the surrounding area SA as well as the display area DA. The stacked film FL1 is divided into a plurality of parts by the partition 6 having an overhang shape. The sealing layer SE11 continuously covers the parts into which the stacked film FL1 is divided, and the partition 6.

Next, the stacked film FL1 and the sealing layer SE11 are patterned. In this patterning, as shown in FIG. 9G, a resist R3 is provided on the sealing layer SE11. The resist R3 covers the subpixel SP1 and part of the partition 6 around the subpixel SP1.

After that, an etching process using the resist R3 as a mask is performed. As a result, as shown in FIG. 9H, the parts of the stacked film FL1 and the sealing layer SE11, which are exposed from the resist R3, are removed and the display element DE1 is formed on the sub-pixel SP1. This etching process includes wet etching and dry etching which are performed in order for the sealing layer SE11, the cap layer CP1, the upper electrode UE1, and the organic layer OR1. After these etching processes, the resist R3 is removed (peeled off).

Incidentally, the stacked film FL1 located under the sealing layer SE11 on the partition 6 is also removed in wet etching for the stacked film FL1. As a result, a gap is formed between the sealing layer SE11 located above the partition 6 and the partition 6. Since the stacked film FL1 which constitutes the display element DE1 is completely surrounded by the sealing layer SE11 and the partition 6, this stacked film FL1 is not corroded by the above-described wet etching.

Prior to the above-described wet etching, the laminated film FL1 is also formed in the gap between the partition 6 and the sealing layer SE11. The stacked film FL1 in this gap is removed as the etchant penetrates from the vicinity of the end portion of the sealing layer SE11 to the lower side of the sealing layer SE11 in the wet etching.

After the process PR6, a process for forming the display element DE2 is performed (process PR7 in FIG. 8). The display element DE2 can be formed in the same procedure as that of the display element DE1. In other words, to form the display element DE2, the stacked film FL2 and the sealing layer SE12 are formed over the entire display area DA and the surrounding area SA. As shown in FIG. 3, the stacked film FL2 includes the organic layer OR2 which is in contact with the lower electrode LE2 through the pixel aperture AP2, the upper electrode UE2 which covers the organic layer OR2, and the cap layer CP2 which covers the upper electrode UE2.

The organic layer OR2, the upper electrode UE2, and the cap layer CP2 can be formed by, for example, vapor deposition. In addition, the sealing layer SE12 can be formed by, for example, CVD. The stacked film FL2 is divided into a plurality of parts by the partition 6 having an overhang shape. The sealing layer SE12 continuously covers the parts into which the stacked film FL2 is divided, and the partition 6. By patterning the stacked film FL2 and the sealing layer SE2, the display element DE2 is formed in the subpixel SP2 as shown in FIG. 9I.

The end portions of the sealing layers SE11 and SE12 located above the partition 6 between the subpixels SP1 and SP2 are in contact with each other. When the sealing layer SE12 is formed to be in contact with the sealing layer SE11, a protruding portion 121a may be formed in the overlapping portion SE121, in the sealing layer SE12 formed in the process following the sealing layer SE11. Furthermore, an extending portion 121b that extends toward the gap G1 formed between the sealing layer SE11 and the upper portion 62 of the partition 6 may be formed in the sealing layer SE12.

Incidentally, the stacked film FL2 is also formed in the gap between the partition 6 and the sealing layer SE12. The stacked film FL2 in this gap is removed as the etchant penetrates from the vicinity of the end portion of the sealing layer SE12 to the lower side of the sealing layer SE12 in the wet etching.

After the process PR7, a process for forming the display element DE3 is performed (process PR8 in FIG. 8). The display element DE3 can be formed in the same procedure as the procedures of the display elements DE1 and DE2.

In other words, to form the display element DE3, the stacked film FL3 and the sealing layer SE13 are formed over the entire display area DA and the surrounding area SA. As shown in FIG. 3, the stacked film FL3 includes the organic layer OR3 which is in contact with the lower electrode LE3 through the pixel aperture AP3, the upper electrode UE3 which covers the organic layer OR3, and the cap layer CP3 which covers the upper electrode UE3.

The organic layer OR3, the upper electrode UE3 and the cap layer CP3 can be formed by, for example, vapor deposition. In addition, the sealing layer SE13 can be formed by, for example, CVD. The stacked film FL3 is divided into a plurality of parts by the partition 6 having an overhang shape. The sealing layer SE13 continuously covers the parts into which the stacked film FL3 is divided, and the partition 6. By patterning the stacked film FL3 and the sealing layer SE13, the display element DE3 is formed in the subpixel SP3 as shown in FIG. 9J.

The end portions of the sealing layers SE11 and SE13 located above the partition 6 between the subpixels SP1 and SP3 are in contact with each other. When the sealing layer SE13 is formed to be in contact with the sealing layer SE11, a protruding portion 131a may be formed in the overlapping portion SE131, in the sealing layer SE13 formed in the process following the sealing layer SE11. Furthermore, an extending portion 131b that extends toward the gap G1 formed between the sealing layer SE11 and the upper portion 62 of the partition 6 may be formed in the sealing layer SE13.

As shown in FIG. 9J, a stacked film FL3 is formed in the gap between the partition 6 and the sealing layer SE13. Since the end portions of the sealing layer SE11 and the sealing layer SE13 are in contact with each other, penetration of the etchant from the vicinity of the end portion of the sealing layer SE13 toward the lower side of the sealing layer SE13 during the wet etching is suppressed. As a result, the stacked film FL3 remains in this gap.

Furthermore, this gap is surrounded not only by the partition 6 and the overlapping portion SE131, but also by the protruding portion 131b. Consequently, penetration of the etchant into the gap is further suppressed.

Incidentally, when the sealing layer SE13 is formed to be in contact with the sealing layer SE12 even above the partition 6 between the subpixels SP2 and SP3, the protrusion 131, and the extending portion 131b extending toward the gap formed between the sealing layer SE11 and the upper portion 62 of the partition 6 may be formed at the overlapping portion SE131, in the sealing layer SE13 formed in the process following the sealing layer SE12.

In addition, in the examples shown in FIG. 9I and FIG. 9J, the portion 121c of the sealing layer SE12, which overlaps with the sealing layer SE11, and the portion 131c of the sealing layer SE13, which overlaps with the sealing layer SE11, as shown in FIG. 4, are removed. However, patterning may be performed such that the portions 121c and 131c remain.

After the process PR8, the resin layer RS1, the sealing layer SE2, and the resin layer RS2 are formed in order (process PR9 in FIG. 8). To form the resin layers RS1 and RS2, for example, an ink-jet method can be used. To form the sealing layer SE2, for example, CVD can be used.

In the present embodiment, it is assumed that the display elements DE1, DE2, and DE3 are formed in this order. In this case, the display element DE1 corresponds to the display element of the first color, the display element DE2 corresponds to the display element of the second color, and the display element DE3 corresponds to the display element of the third color.

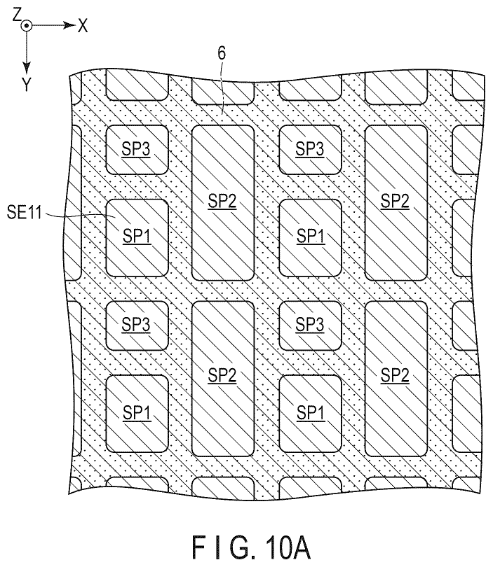

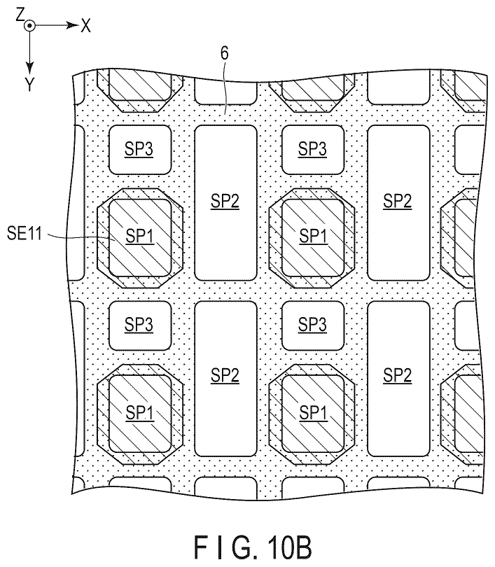

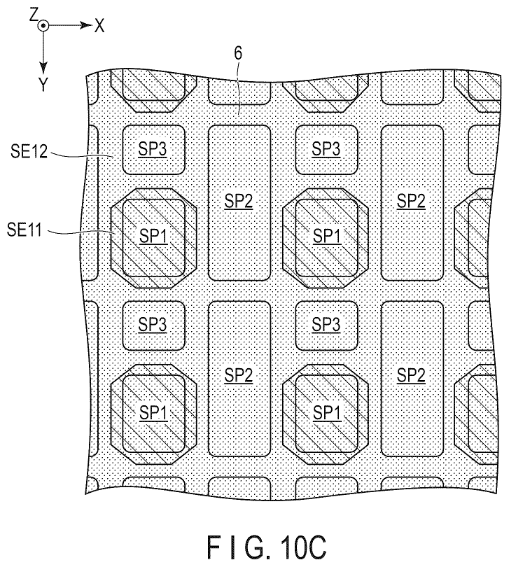

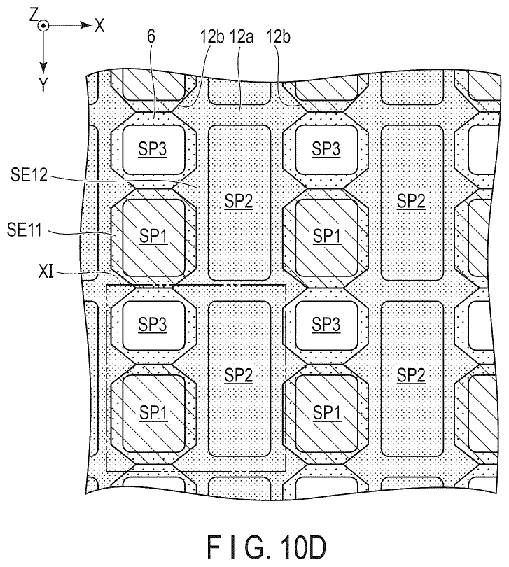

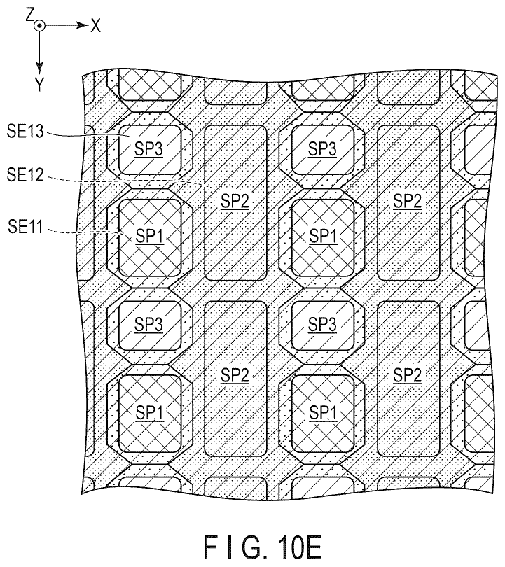

Focus on the sealing layers SE11, SE12, and SE13 in the processes PR6 to PR8 of FIG. 8 will be made here. Each of FIG. 10A to FIG. 10E is a schematic plan view showing the manufacturing process of the display device DSP.

In the process PR6 of FIG. 8, as shown in FIG. 10A, the sealing layer SE11 is formed over the entire display area DA. After the process PR6 of FIG. 8, the sealing layer SE11 shown in FIG. 10B is formed. As described above, the sealing layer SE11 has an octagonal shape.

In the process PR7 of FIG. 8, as shown in FIG. 10C, the sealing layer SE12 is formed over the entire display area DA. After the process PR7 of FIG. 8, the sealing layer SE12 shown in FIG. 10D is formed. During the patterning of the process PR7, a plurality of outwardly extending portions 12b are formed.

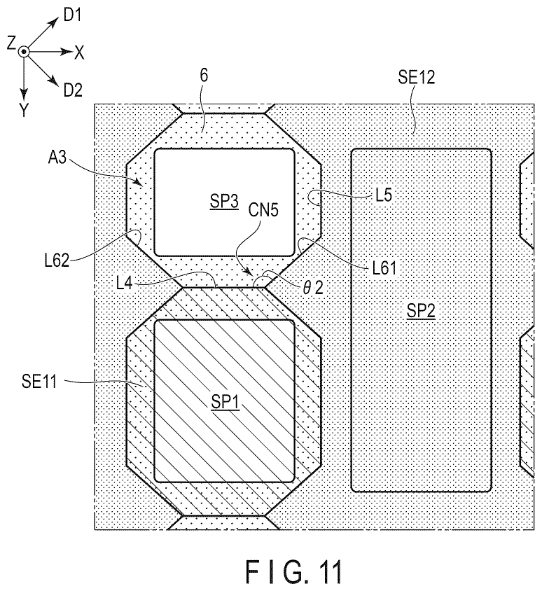

FIG. 11 is a schematic enlarged view showing a XI portion in FIG. 10D. The sealing layer SE11 has a side L4, and the sealing layer SE12 has sides L5, L61, and L62. In the present embodiment, the side L4 corresponds to a fourth side, the side L5 corresponds to a fifth side, and the side L61 corresponds to a sixth side.

The side L4 extends in the first direction X. The side L5 extends in the second direction Y. The sides L61 and L62 are parts of the outwardly extending region 12b. The sides L61 and L62 are connected to the side L5. The sides L61 and L62 extend in directions different from the first direction X and the second direction Y.

The side L61 extends in, for example, direction D1 which intersects the first direction X at an acute angle counterclockwise. The side L62 extends in, for example, direction D2 which intersects the first direction X at an acute angle counterclockwise. The sides L61 and L62 are directly connected to the side L5 in the example of FIG. 11, but the sides L61 and L62 may also be connected to the side L5 via other sides.

In addition, focus on the relationship with the partition 6 will be made here. Each of the sides L4, L5, L61, and L62 overlaps with the partition 6. In other words, the sides L4, L5, L61, and L62 are provided above the upper portion 62 of the partition 6.

Focus on the sealing layer SE13 will be made here. The side L4 corresponds to a side of the sealing layer SE13, which is in contact with the side L1 (shown in FIG. 6). In addition, the side L5 corresponds to a side of the sealing layer SE13, which is in contact with the side L2 (shown in FIG. 6), the side L61 corresponds to a side of the sealing layer SE13, which is in contact with the side L31 (shown in FIG. 6), and the side L62 corresponds to a side of the sealing layer SE13, which is in contact with the side L32 (shown in FIG. 6).

An angle formed by the side L4 and the side L61 is defined as angle θ2. In addition, an area surrounded by the sealing layer SE11 and the sealing layer SE12 is defined as area A3. In other words, the sealing layers SE11 and SE12 form the area A3. The area A3 corresponds to an area overlapping with the subpixel SP3 (lower electrode LE3). The planar shape of the area A3 is an octagonal shape.

Focus on the area A3 will be made here. The angle θ2 corresponds to an interior angle of area A3. The angle θ2 is, for example, an obtuse angle. In other words, the angle θ2 is greater than 90 degrees and smaller than 180 degrees (90 degrees<θ2<180 degrees). In one example, the angle θ2 is 120 degrees or more and 150 degrees or less (120 degrees<θ2<150 degrees). More specifically, the angle θ2 is 135 degrees. In this case, the angle formed by the side L61 and the side L62 (the interior angle of the sealing layer SE12) is 90 degrees. Incidentally, the other interior angles in the area A3 are also configured similarly to the angle θ2.

In the process PR8 of FIG. 8, as shown in FIG. 10E, the sealing layer SE13 is formed over the entire display area DA. After the process PR8 of FIG. 8, the sealing layer SE13 shown in FIG. 5 is formed.

According to the above-described embodiment, the yield of the display device DSP can be improved.

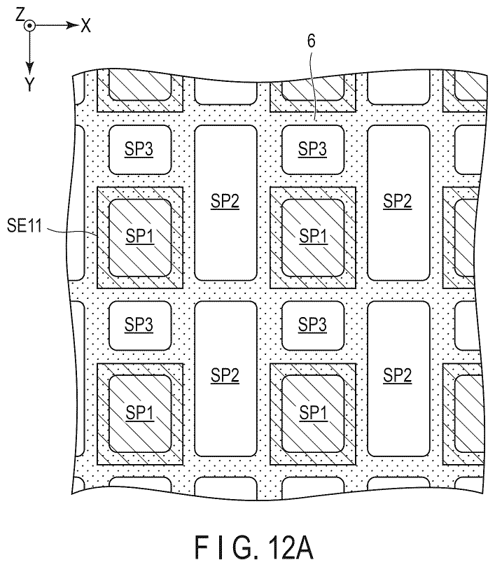

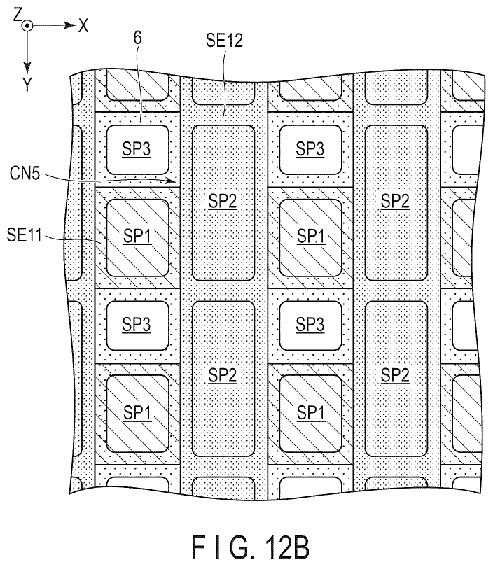

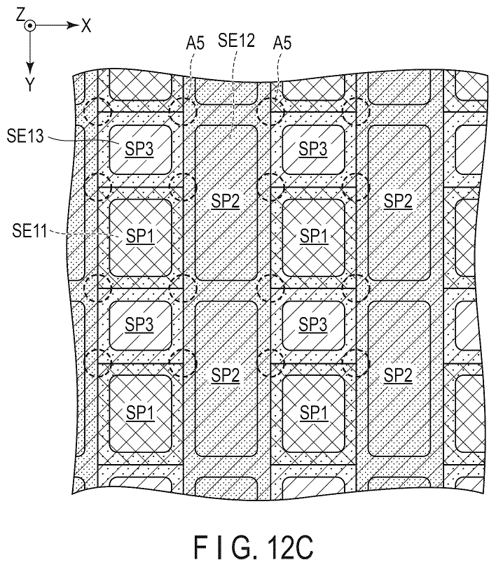

Each of FIG. 12A to FIG. 12C is a schematic plan view showing a process of manufacturing a display device according to a comparative example of the present embodiment. In FIG. 12A to FIG. 12C, focus on the sealing layers SE11, SE12, and SE13 is made, similarly to FIG. 10A to FIG. 10E.

In the comparative example, as shown in FIG. 12A, the sealing layer SE11 covering the stacked film FL1 of the display element DE1 is formed. The sealing layer SE11 has a rectangular shape in plan view. After that, a process for forming the display element DE2 is performed. In the comparative example, as shown in FIG. 12B, the sealing layer SE12 covering a plurality of subpixels SP2 is formed. Focus on the corner portion CN5 formed by the sealing layer SE11 and the sealing layer SE12 will be made here. The corner portion CN5 is formed in a shape of a right angle.

After that, a process for forming the display element DE3 is performed. To form the display element DE3, as shown in FIG. 12C, the stacked film FL3 and the sealing layer SE13 are formed over the entire display area DA. Then, a resist for processing the stacked film FL3 and the sealing layer SE13 is applied. When applying the resist, air bubbles are likely to be formed at positions overlapping with the corner portion CN5.

If a process for forming the display element DE3 is performed in a state where air bubbles are formed, the air bubble burst at the time of the reduced-pressure drying of the resist for patterning the stacked film FL3 and the sealing layer SE13, and the area A5 (shown in FIG. 12C) which needs to be covered with the resist is exposed. As a result, defects may occur in the display area DA.

In contrast, as shown in FIG. 11, the interior angle (angle θ2) of the area A3 formed by the sealing layer SE11 and the sealing layer SE12 is formed as an obtuse angle, in the display device DSP according to the present embodiment. For this reason, the sealing layer SE13 having an obtuse angle θ1 (interior angle) is formed.

As a result, when the resist for patterning the stacked film FL3 and the sealing layer SE13 is applied, air can easily escape from the corner portion CN5. In other words, during the process PR8, air bubbles are less likely to be formed and the resist easily flows in the corner portion CN5 (interior angle of area A3).

As a result, splattering of the resist during the process PR8 can be suppressed. In other words, the area A5 which needs to be covered with the resist is less likely to be exposed. In the present embodiment, occurrence of defects in the display device DSP can be suppressed, and the yield of the display device DSP can be thereby improved.

Next, other embodiments will be described. Incidentally, in the other embodiments described below, the same components as those of the above-described first embodiment may be denoted by the same reference numerals as those in the first embodiment, and their detailed description may be omitted or simplified.

### Second Embodiment

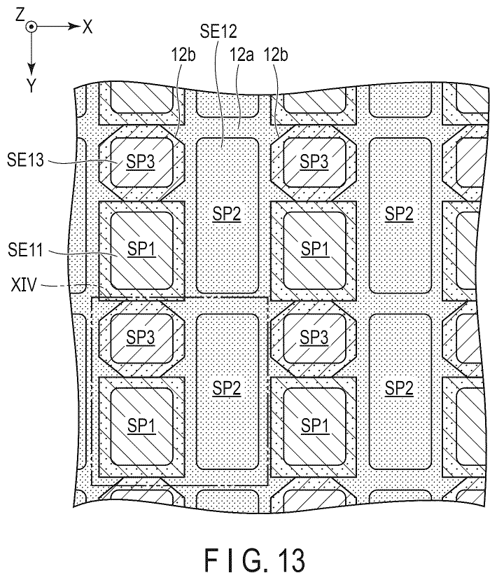

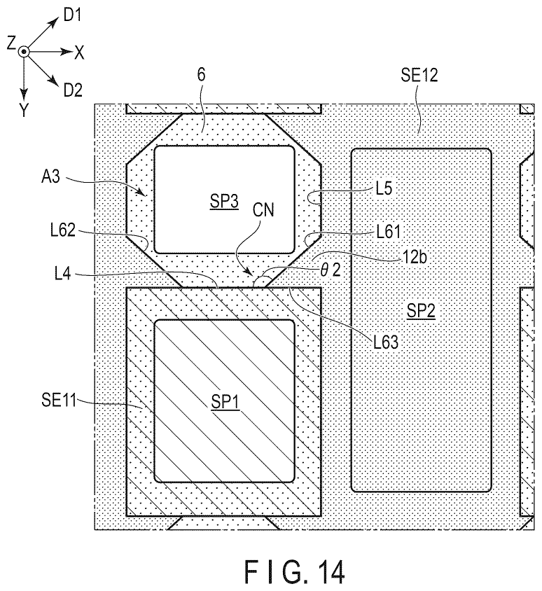

FIG. 13 is a schematic plan view showing a display device DSP according to the present embodiment. FIG. 14 is a schematic enlarged view showing a XIV portion in FIG. 13. In FIG. 14, focus on the sealing layers SE11 and SE12 is mainly made and the other elements such as the sealing layer SE13 are omitted. Shapes of the sealing layers SE11 and SE12 in the present embodiment are different from those in the first embodiment.

The sealing layer SE11 has a rectangular shape in plan view. The sealing layer SE11 has a side L4 extending in the first direction X as shown in FIG. 14. For example, the sealing layers SE12 are continuously formed over a plurality of subpixels SP2 arranged in the second direction Y.

The sealing layer SE12 has a plurality of outwardly extending portions 12b as shown in FIG. 14. A shape of the outwardly extending portions 12b in the present embodiment is different from the shape of the outwardly extending portions 12b in the first embodiment.

The sealing layer SE12 has sides L5, L61, and L62. The outwardly extending portions 12b include an outwardly extending portion 12b including the side L61 and an outwardly extending portion 12b including the side L62. The sealing layer SE12 further has a side L63 at an outwardly extending portion 12b as shown in FIG. 14. The side L63 extends in the first direction X along the side L4 of the sealing layer SE11. Each of the sides L61 and L62 is connected to the side L63.

In the present embodiment as well, the angle θ2 is, for example, an obtuse angle. In other words, the angle θ2 is greater than 90 degrees and smaller than 180 degrees (90 degrees<θ2<180 degrees). In one example, the angle θ2 is 120 degrees or more and 150 degrees or less (120 degrees<θ2<150 degrees). More specifically, the angle θ2 is 135 degrees. Incidentally, the sealing layer SE13 in the present embodiment has the same shape as the sealing layer SE13 in the first embodiment.

The same advantages as those of the first embodiment can also be obtained in the present embodiment. In the present embodiment as well, the angle θ2 is formed as an obtuse angle. Thus, when the resist for patterning the stacked film FL3 and the sealing layer SE13 is applied, air can easily escape from the corner portion CN5. As a result, splattering of the resist during the process PR8 in FIG. 8 can be suppressed. In the present embodiment, occurrence of defects in the display device DSP can be suppressed, and the yield of the display device DSP can be thereby improved.

### Third Embodiment

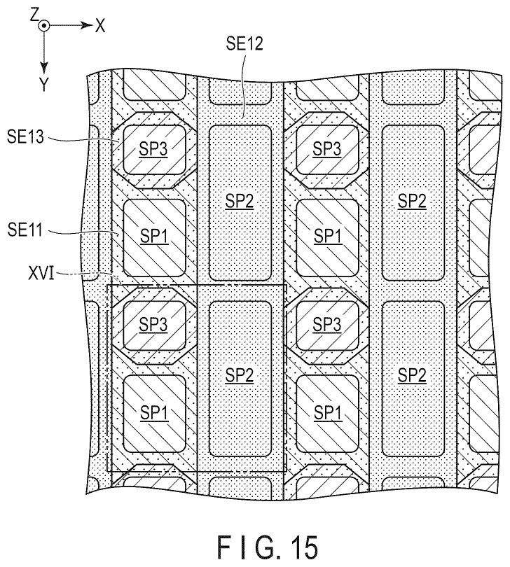

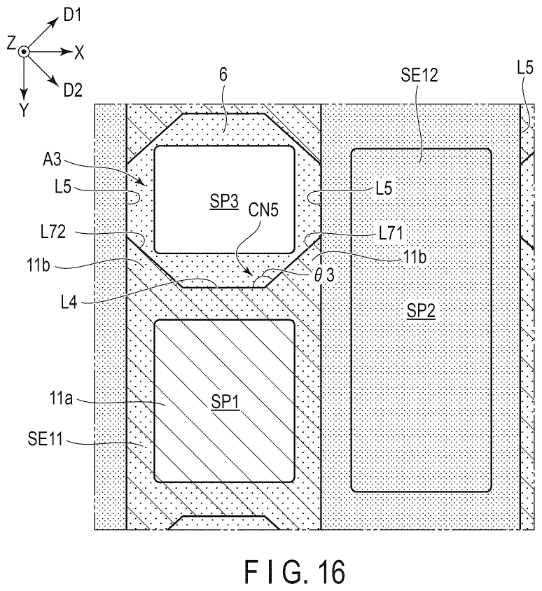

FIG. 15 is a schematic plan view showing a display device DSP according to the present embodiment. FIG. 16 is a schematic enlarged view showing a XVI portion in FIG. 15. In FIG. 16, focus on the sealing layers SE11 and SE12 is mainly made and the other elements such as the sealing layer SE13 are omitted. Shapes of the sealing layers SE11 and SE12 in the present embodiment are different from those in the first embodiment.

The sealing layer SE12 is continuously formed over a plurality of subpixels SP2 arranged in the second direction Y as shown in FIG. 15. The sealing layer SE12 in the present embodiment does not include elements corresponding to the outwardly extending portions 12b in the first embodiment. The sealing layer SE12 has a pair of sides L5 extending in the second direction as shown in FIG. 16.

The sealing layer SE11 includes a main body 11a overlapping with the subpixel SP1, and a plurality of (four) outwardly extending portions 11b, as shown in FIG. 16. The outwardly extending portions 11b are formed by, for example, the patterning of the process PR6. The outwardly extending portions 11b extend from the main body 11a toward an outside of the subpixel SP1. More specifically, the plurality of outwardly extending portions 11b extend in the second direction Y and a direction opposite to the second direction Y.

The plurality of outwardly extending portions 11b are provided above the partition 6. The sealing layer SE11 has two sides L4, two sides L71, and two sides L72. In the present embodiment, the side L4 corresponds to a fourth side, and the side L71 corresponds to a seventh side.

The side L4 corresponds to a side of the sealing layer SE13, which is in contact with the side L1 (shown in FIG. 6), the side L71 corresponds to a side of the sealing layer SE13, which is in contact with the side L31 (shown in FIG. 6), and the side L72 corresponds to a side of the sealing layer SE13, which is in contact with the side L32 (shown in FIG. 6). The outwardly extending portions 11b include an outwardly extending portion 11b including the side L71 and an outwardly extending portion 11b including the side L72. The sides L71 and L72 extend in directions different from the first direction X and the second direction Y.

The side L71 extends in, for example, direction D1 which intersects the first direction X at an acute angle counterclockwise. The side L72 extends in, for example, direction D2 which intersects the first direction X at an acute angle counterclockwise. The sides L71 and L72 are directly connected to the side L4, but may also be connected to the side L4 via other sides.

In addition, focus on the relationship with the partition 6 will be made here. Each of the sides L4, L71, and L72 overlaps with the partition 6. In other words, the sides L4, L71, and L72 are provided above the upper portion 62 of the partition 6.

An angle formed by the side L4 and the side L71 is defined as angle θ3. Focus on the area A3 will be made here. The angle θ3 corresponds to an interior angle of area A3. The angle θ3 is, for example, an obtuse angle. In other words, the angle θ3 is greater than 90 degrees and smaller than 180 degrees (90 degrees<θ3<180 degrees). In one example, the angle θ3 is 120 degrees or more and 150 degrees or less (120 degrees<θ3<150 degrees). More specifically, the angle θ3 is 135 degrees. Incidentally, the other interior angles in the area A3 are also configured similarly to the angle θ3.

The same advantages as those of the first embodiment can also be obtained in the present embodiment. In the present embodiment, the angle θ3 is formed as an obtuse angle. Thus, when the resist for patterning the stacked film FL3 and the sealing layer SE13 is applied, air can easily escape from the corner portion CN5. As a result, splattering of the resist during the process PR8 in FIG. 8 can be suppressed. In the present embodiment, occurrence of defects in the display device DSP can be suppressed, and the yield of the display device DSP can be thereby improved.

### Fourth Embodiment

Next, the fourth embodiment will be described. In each of the above-described embodiments, it is assumed that the display elements DE1, DE2, and DE3 are formed in this order. In the present embodiment, it is assumed that the display element DE2 is first formed and then the display elements DE1 and DE3 are formed. In the present embodiment, the display element DE2 corresponds to the display element of the first color, the display element DE1 corresponds to the display element of the second color, and the display element DE3 corresponds to the display element of the third color. In this case as well, the above-described phenomenon that the resists burst may occur when the display element DE3 is formed.

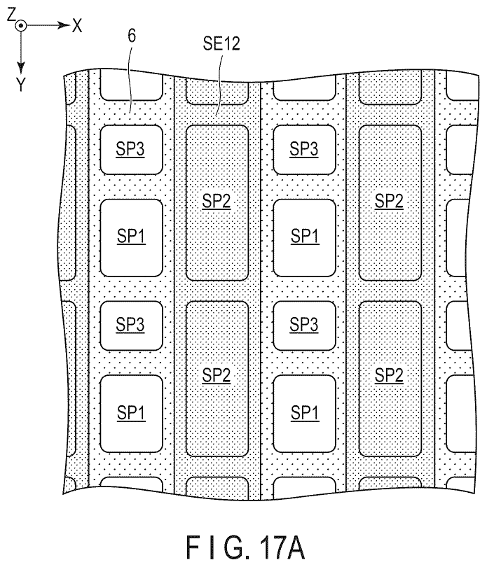

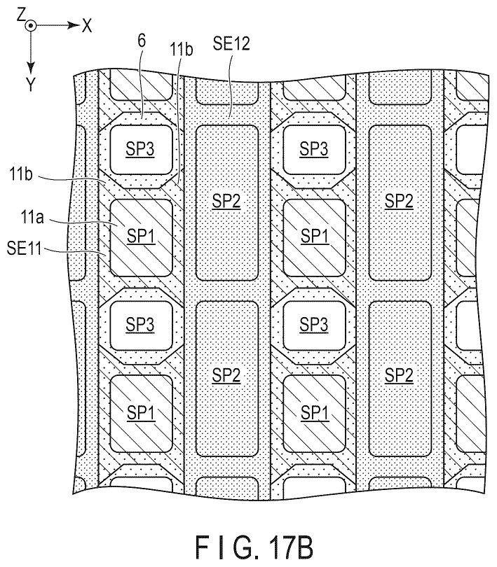

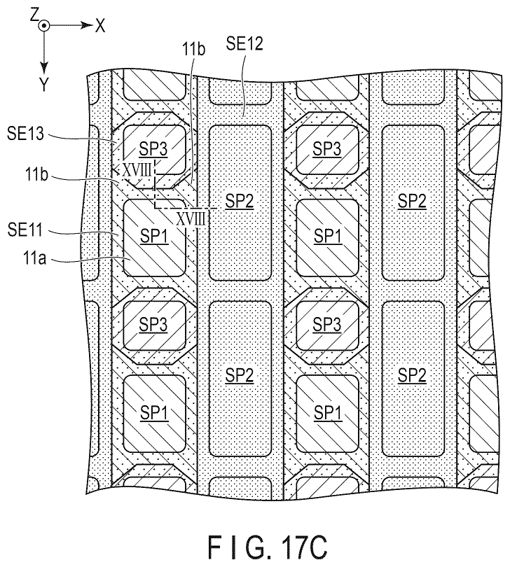

Each of FIG. 17A to FIG. 17C is a schematic plan view showing a process of manufacturing a display device DSP according to the present embodiment.

As shown in FIG. 17A, a sealing layer SE12 is formed in a display area DA. After the formation of the display element DE2, a sealing layer SE11 is formed as shown in FIG. 17B. The sealing layer SE11 has a plurality of outwardly extending portions 11b. After the formation of the display element DE1, a sealing layer SE13 is formed as shown in FIG. 17C.

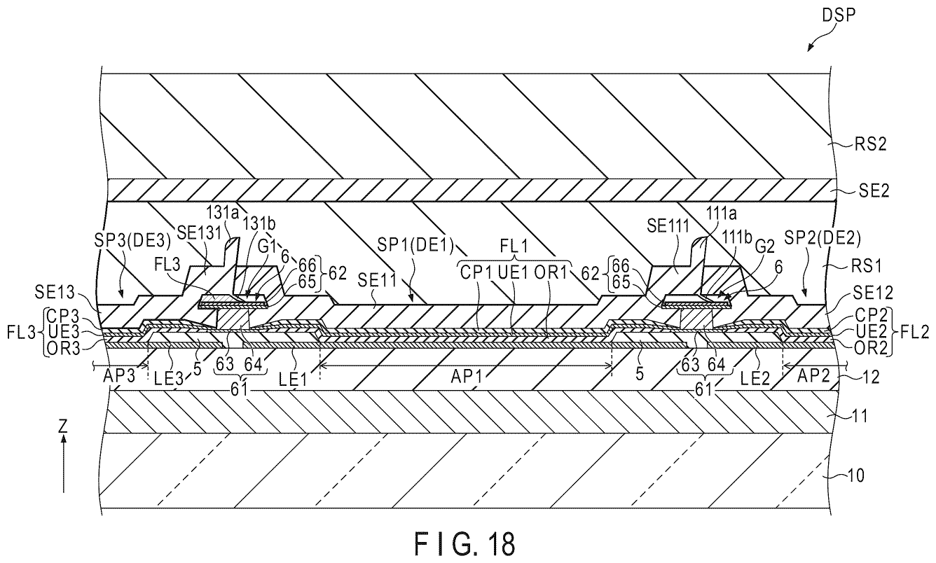

FIG. 18 is a schematic cross-sectional view showing the display device DSP along XVIII-XVIII line in FIG. 17C.

In the present embodiment as well, the end portions of the sealing layers SE11 and SE12 located above the partition 6 between the subpixels SP1 and SP2 are in contact with each other. In addition, the end portions of the sealing layers SE11 and SE13 located on the partition 6 between the subpixels SP1 and SP3 are in contact with each other. Furthermore, although not shown in the figure, the end portions of the sealing layers SE12 and SE13 located on the partition 6 between the subpixels SP2 and SP3 are in contact with each other.

Focus on the sealing layer SE11 will be made here. The sealing layer SE11 has an overlapping portion SE111 located above the partition 6. The overlapping portion SE111 may include a protruding portion 111a (third protruding portion) that protrudes upwardly. The protruding portion 111a is located above the partition 6 between the subpixels SP1 and SP2 so as to be higher than the sealing layer SE12.

In addition, the overlapping portion SE111 may further include an extending portion 111b that extends toward a gap G2 formed between the sealing layer SE12 and the upper portion 62 of the partition 6. This gap occurs due to disappearance of the stacked film FL1 during the manufacturing process.

The stacked film FL1 may be provided between the partition 6 and the overlapping portion SE111. Incidentally, this stacked film FL1 may disappear during the manufacturing process. In this case, a gap occurs between the sealing layer SE11 and the partition 6.

Similarly, focus on the sealing layer SE13 will be made here. The sealing layer SE13 has an overlapping portion SE131 located above the partition 6. The overlapping portion SE131 may include a protruding portion 131a that protrudes upwardly. The protruding portion 131a is located above the partition 6 between the subpixels SP1 and SP3 so as to be higher than the sealing layer SE11.

In addition, the overlapping portion SE131 may further include an extending portion 131b that extends toward a gap formed between the sealing layer SE11 and the upper portion 62 of the partition 6. This gap occurs due to disappearance of the stacked film FL1 during the manufacturing process.

The stacked film FL3 may be provided between the partition 6 and the overlapping portion SE131. Incidentally, if this stacked film FL3 disappears during the manufacturing process, a gap occurs between the sealing layer SE13 and the partition 6.

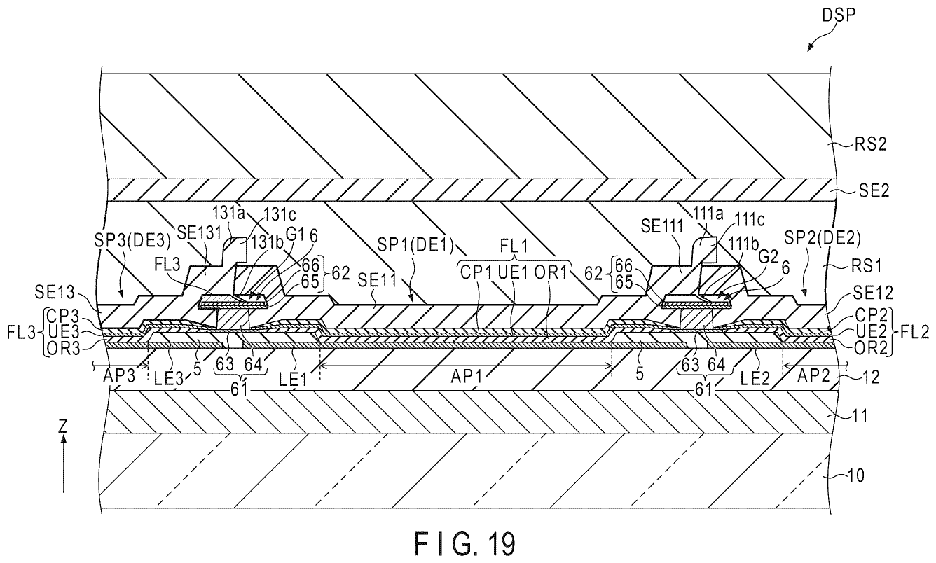

FIG. 19 is a schematic cross-sectional view showing another example of the display device DSP according to the present embodiment. In FIG. 19, the shapes of the overlapping portions SE111 and SE131 of the sealing layers SE11 and SE13 are different from those in the example shown in FIG. 18.

Focus on the sealing layer SE11 will be made here. The protruding portion 111a of the sealing layer SE11 may overlap with the sealing layer SE12. In the example of FIG. 19, the protruding portion 111a includes a portion 111c that overlaps with the sealing layer SE12. The partition 6, the sealing layer SE12, and the protruding portion 111a of the sealing layer SE11 are arranged in this order in the third direction Z.

Similarly, focus on the sealing layer SE13 will be made here. The protruding portion 131a of the sealing layer SE13 may overlap with the sealing layer SE11. In the example of FIG. 19, the protruding portion 131a includes a portion 131c that overlaps with the sealing layer SE11. The partition 6, the sealing layer SE11, and the protruding portion 131a of the sealing layer SE13 are arranged in this order in the third direction Z.

Although not shown in FIG. 18 or FIG. 19, focus on the area above the partition 6 between the subpixels SP2 and SP3 will be made here. The overlapping portion SE131 may include a protruding portion 131a that protrudes upwardly. The protruding portion 131a is located above the sealing layer SE12. In addition, in the example of FIG. 19, the partition 6, the sealing layer SE12, and the protrusion 131a of the sealing layer SE13 are provided above the partition 6 between the subpixels SP2 and SP3 and arranged in this order in the third direction Z.

The same advantages as those of the third embodiment can also be obtained in the present embodiment. Incidentally, the order in which the display elements DE1, DE2, and DE3 are formed in the present embodiment can also be applied to the first embodiment and the second embodiment.

### Fifth Embodiment

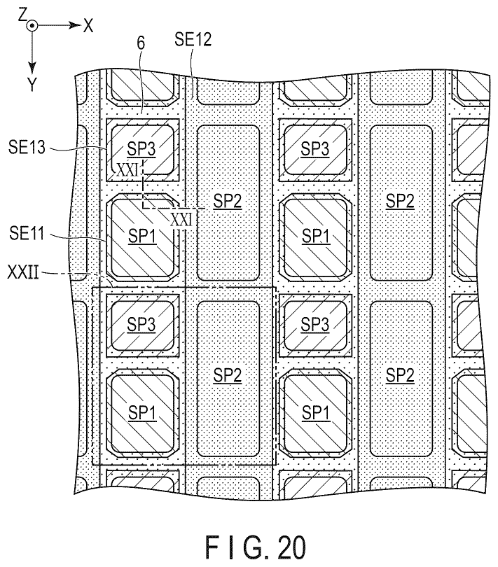

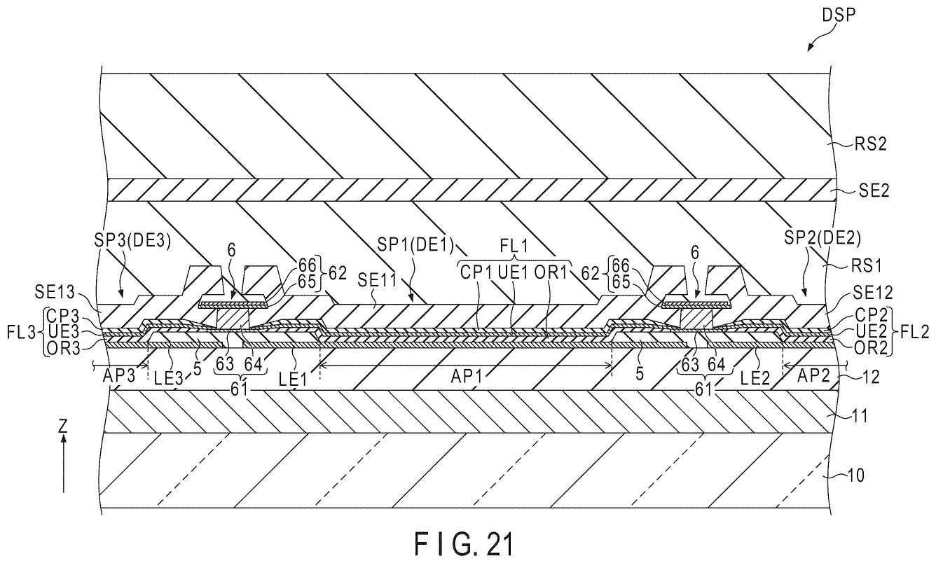

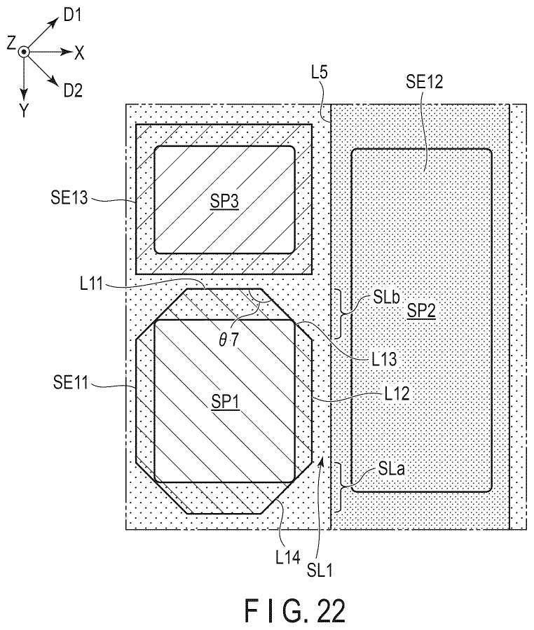

FIG. 20 is a schematic plan view showing a display device DSP according to the present embodiment. FIG. 21 is a schematic cross-sectional view showing the display device DSP along XXI-XXI line in FIG. 20. FIG. 22 is a schematic enlarged view showing a XXII portion in FIG. 20. In the present embodiment, arrangement of sealing layers SE11, SE12, and SE13 is different from that in each of the above-described embodiments.

More specifically, the sealing layers SE11, SE12, and SE13 located above a partition 6 are spaced apart from each other. In other words, an end portion of the sealing layer SE12 is not in contact with an end portion of the sealing layer SE11, and an end portion of the sealing layer SE13 is not in contact with each of end portions of the sealing layers SE11 and SE12.

A planar shape of the sealing layer SE11 is an octagonal shape. For example, the sealing layers SE12 are continuously formed over a plurality of subpixels SP2 arranged in the second direction Y. A planar shape of the sealing layer SE13 is a rectangular shape.

In the example of FIG. 21, the sealing layer SE11 located on the partition 6 between subpixels SP1 and SP2 is spaced apart from the sealing layer SE12 located on this partition 6. In addition, the sealing layer SE11 located on the partition 6 between subpixels SP1 and SP3 is spaced apart from the sealing layer SE13 located on this partition 6.

For example, gaps are formed between the sealing layers SE11, SE12, and SE13, and the upper portion 62 of the partition 6. The stacked films FL1, FL2, and FL3 may be provided in at least some of these gaps.

Focus on the sealing layer SE11 and the sealing layer SE12 will be made here. As shown in FIG. 22, a slit SL1 is formed between the sealing layer SE11 and the sealing layer SE12. The slit SL1 extends in the second direction Y. The slit SL1 is located above the partition 6 between the subpixels SP1 and SP2.

The sealing layer SE11 has two sides L11, two sides L12, two sides L13, and two sides L14 as shown in FIG. 22. In the present embodiment, the side L11 corresponds to a first side, the side L12 corresponds to a second edge, and the side L13 corresponds to a third side.

The side L11 extends in the first direction X, and the side L12 extends in the second direction Y. The sides L13 and L14 connect the sides L11 and L12. The sides L13 and L14 extend in directions different from the first direction X and the second direction Y.

An angle formed by the side L11 and the side L13 is defined as angle θ7. Focus on the sealing layer SE11 will be made here. The angle θ7 corresponds to an interior angle of the sealing layer SE11. The angle θ7 is, for example, an obtuse angle. In other words, the angle θ7 is greater than 90 degrees and smaller than 180 degrees (90 degrees<θ7<180 degrees). In one example, the angle θ7 is 120 degrees or more and 150 degrees or less (120 degrees<θ7<150 degrees). More specifically, the angle θ7 is 135 degrees.

The slit SL1 has end portions SLa and SLb. The end portion SLa is located between the side L14 of the sealing layer SE11 and a side L5 of the sealing layer SE12, and the end portion SLb is located between the side L13 of the sealing layer SE11 and the side L5 of the sealing layer SE12.

The end portion SLa of the slit SL1 has a width in the first direction X greater toward the second direction Y, and the end portion SLb has a width in the first direction X greater toward a direction opposite to the second direction Y.

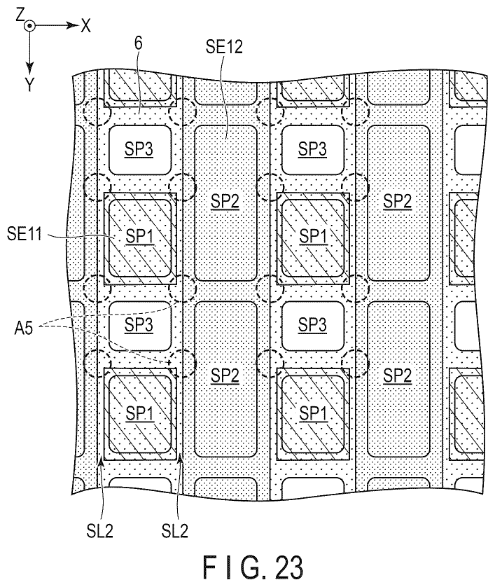

The same advantages as those of the first embodiment can also be obtained in the present embodiment. FIG. 23 is a schematic plan view showing a display device DSP according to a comparative example of the present embodiment. FIG. 23 shows a state in which the display element DE3 is to be formed.

In the comparative example, a slit SL2 is formed between the sealing layers SE11 and SE12. The comparative example is different from the present embodiment in that a planar shape of the sealing layer SE11 is a rectangular shape.

In this case, the width of the slit SL2 in the first direction X is substantially constant in the second direction Y. For this reason, when the process for forming the display element DE3 is performed, air bubbles are likely to be formed near apertures at end portions of the slit SL2.

If a process for forming the display element DE3 is performed in a state where air bubbles are formed, the air bubble burst at the time of the reduced-pressure drying of the resist for patterning the stacked film FL3 and the sealing layer SE13, and the area A5 which needs to be covered with the resist is exposed. As a result, defects may occur in the display area DA.

In contrast, as shown in FIG. 22, the end portions SLa and SLb are formed at the slit SL1 by forming the angle θ7 at the corner portion of the sealing layer SE11 as an obtuse angle, in the display device DSP according to the present embodiment.

Consequently, when the stacked film FL3 and the sealing layer SE13 are formed, air easily escapes from the end portions SLa and SLb of the slit SL1. In other words, the resist easily flows into the slit SL1 and air bubbles are hardly formed.

As a result, splattering of the resist is suppressed, and the area A5 which is to be covered with the resist is hardly exposed. In the present embodiment, occurrence of defects in the display device DSP can be suppressed, and the yield of the display device DSP can be thereby improved.

According to the display device DSP configured as described above, the yield can be improved. In addition, various desirable effects can be obtained from the present embodiment.

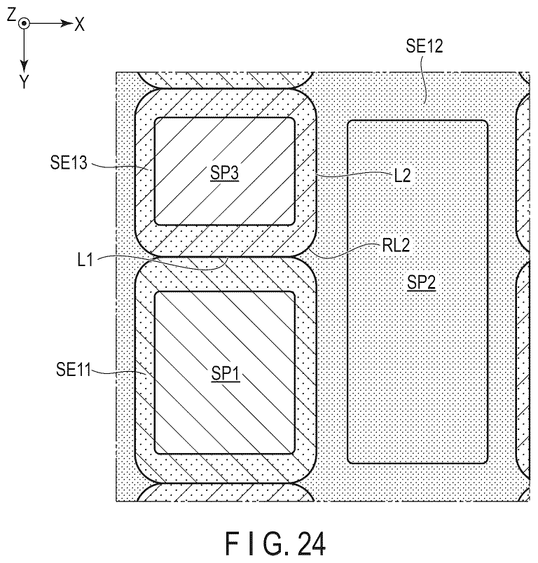

Incidentally, the shape of the area A3 shown in FIG. 11 is not limited to the above-described example. FIG. 24 is a schematic plan view showing a modified example of the display device. In the example of FIG. 24, corner portions of the area A3 are formed to have an arc shape. In other words, the sealing layer SE13 has an arc-shaped curved portion RL2 that connects the side L1 with the side L2. From the other viewpoint, the corner portions of the area A3 surrounded by the sealing layers SE11 and SE12 have an arc shape. In this case, the same advantages as those of each of the above-described embodiments can also be obtained.

All of the display devices that can be implemented by a person of ordinary skill in the art through arbitrary design changes to the display device described above as the embodiment of the present invention come within the scope of the present invention as long as they are in keeping with the spirit of the present invention. Various modified examples which may be conceived by a person of ordinary skill in the art in the scope of the idea of the present invention will also fall within the scope of the invention. For example, even if a person of ordinary skill in the art arbitrarily modifies each of the above embodiments by adding or deleting a structural element or changing the design of a structural element, or adding or omitting a step or changing the condition of a step, all of the modifications fall within the scope of the present invention as long as they are in keeping with the spirit of the invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is

1. A display device comprising:
a lower electrode;
a partition surrounding the lower electrode;
a stacked film provided above the lower electrode; and
a sealing layer formed of an inorganic insulating material, covering the stacked film, and provided above the partition, wherein
the sealing layer has in plan view:
a first side extending in a first direction;
a second side extending in a second direction orthogonal to the first direction; and
a third side extending in a direction different from the first direction and the second direction and connecting the first side with the second side, and
an angle formed by the first side and the third side is greater than 90 degrees and smaller than 180 degrees.

2. The display device of claim 1, wherein
the first side, the second side, and the third side overlap with the partition.

3. The display device of claim 2, wherein
the angle is 120 degrees or more and 150 degrees or less.

4. The display device of claim 2, wherein
the first side is directly connected with the third side.

5. The display device of claim 2, wherein
the sealing layer further has an arc-shaped curved portion connecting the first side with the third side.

6. The display device of claim 1, wherein
a planar shape of the sealing layer is an octagonal shape.

7. The display device of claim 1, further comprising:
an inorganic insulating layer provided under the partition and the lower electrode, wherein
the partition includes:
a lower portion provided on the inorganic insulating layer; and
an upper portion provided on the lower portion to protrude from a side surface of the lower portion, and
the first side, the second side, and the third side are provided above the upper portion.

8. A display device comprising:
a first lower electrode, a second lower electrode, and a third lower electrode;
a partition surrounding the first lower electrode, the second lower electrode, and the third lower electrode;
a first stacked film provided above the first lower electrode;
a second stacked film provided above the second lower electrode;
a first sealing layer formed of an inorganic insulating material, covering the first stacked film, and provided above the partition; and
a second sealing layer formed of an inorganic insulating material, covering the second stacked film, and provided above the partition, wherein
the first sealing layer has a fourth side extending in a first direction, in plan view,
the second sealing layer has a fifth side extending in a second direction orthogonal to the first direction, and a sixth side extending in a direction different from the first direction and the second direction and connected with the fifth side, in plan view,
the first sealing layer and the second sealing layer form an area overlapping with the third lower electrode, and
an interior angle of the area, which is an angle formed by the fourth side and the sixth side, is greater than 90 degrees and smaller than 180 degrees.

9. The display device of claim 8, wherein
the fourth side, the fifth side, and the sixth side overlap with the partition.

10. The display device of claim 8, wherein
a planar shape of the area is an octagonal shape.

11. The display device of claim 8, wherein
the interior angle is 120 degrees or more and 150 degrees or less.

12. The display device of claim 8, further comprising:
a third stacked film provided above the third lower electrode; and
a third sealing layer formed of an inorganic insulating material, covering the third stacked film, and provided above the partition, wherein
the fourth side and the sixth side are located above the partition and are in contact with the third sealing layer.

13. The display device of claim 12, wherein
the third sealing layer further includes a protruding portion overlapping with the partition and located above the first sealing layer.

14. The display device of claim 13, wherein
the protruding portion includes a portion overlapping with the first sealing layer.

15. The display device of claim 12, wherein
the third sealing layer further includes a protruding portion located above the partition and extending toward a gap formed between the first sealing layer and the partition.

16. The display device of claim 12, wherein
the third stacked film is located above the partition and provided between the partition and the third sealing layer.

17. A display device comprising:
a first lower electrode, a second lower electrode, and a third lower electrode;
a partition surrounding the first lower electrode, the second lower electrode, and the third lower electrode;
a first stacked film provided above the first lower electrode;
a second stacked film provided above the second lower electrode;
a first sealing layer formed of an inorganic insulating material, covering the first stacked film, and provided above the partition; and
a second sealing layer formed of an inorganic insulating material, covering the second stacked film, and provided above the partition, wherein
the first sealing layer has a fourth side extending in a first direction, and a seventh side extending in a direction different from a second direction orthogonal to the first direction, and connected with the fourth side, in plan view,
the first sealing layer and the second sealing layer form an area overlapping with the third lower electrode, and
an interior angle of the area, which is an angle formed by the fourth side and the seventh side, is greater than 90 degrees and smaller than 180 degrees.

18. The display device of claim 17, wherein
the fourth side and the seventh side overlap with the partition.

19. The display device of claim 17, further comprising:
a third stacked film provided above the third lower electrode; and
a third sealing layer formed of an inorganic insulating material, covering the third stacked film, and provided above the partition, wherein
the fourth side and the seventh side are located above the partition and are in contact with the third sealing layer.
